(19) United States
(12) Patent Application Publication
(10) Pub. No.: US 2026/0136745 A1
(43) Pub. Date: May 14, 2026

(54) Display Device

(71) Applicant: LG Display Co., Ltd., Seoul (KR)

(72) Inventors: Dae-Il Kang, Gimpo-si (KR); Sungmoo Kim, Goyang-si (KR)

(21) Appl. No.: 19/304,072

(22) Filed: Aug. 19, 2025

(30) Foreign Application Priority Data
Nov. 8, 2024 (KR) 10-2024-0157746

(51) Int. Cl. H10H 29/856; H10H 29/41; H10H 29/80; H10H 29/855

(52) U.S. Cl. CPC H10H 29/856; H10H 29/41; H10H 29/8325; H10H 29/8552

(57) ABSTRACT

A display device includes a first substrate; a planarization layer which is disposed on the first substrate and includes a first top surface, a second top surface having a height lower than that of the first top surface, and an inclined surface; a first reflection electrode which is at least partially disposed on the inclined surface of the planarization layer; a light emitting element on the first reflection electrode; and a second reflection electrode which is disposed so as to cover the light emitting element. The light emitting element is disposed on any one of the first top surface and the second top surface. Accordingly, the first reflection electrode is disposed on the inclined surface to more easily extract light emitted from the light emitting element to the outside.

### CROSS-REFERENCE TO RELATED APPLICATION

This application claims the priority of Republic of Korea Patent Application No. 10-2024-0157746 filed on November 8, 2024, which is hereby incorporated by reference in its entirety.

### FIELD

The present disclosure relates to a display device, and more particularly, to a display device using a light emitting element (LED).

### BACKGROUND

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY

An object to be achieved by the present disclosure is to provide a display device which includes an inorganic light emitting element with excellent luminous efficiency to be driven at a low power.

Another object to be achieved by the present disclosure is to provide a display device with an improved light conversion efficiency and an improved light extraction efficiency.

Still another object to be achieved by the present disclosure is to provide a display device which easily controls a thickness of a light conversion layer.

Still another object to be achieved by the present disclosure is to provide a display device which improves a light extraction efficiency by forming an irregular structure in an area where light emitted from the light emitting element is released.

Objects of the present disclosure are not limited to the above-mentioned objects, and other objects, which are not mentioned above, can be clearly understood by those skilled in the art from the following descriptions.

According to an embodiment of the present disclosure, a display device includes a first substrate; a planarization layer which is disposed on the first substrate and includes a first top surface, a second top surface having a height lower than that of the first top surface, and an inclined surface; a first reflection electrode which is at least partially disposed on the inclined surface of the planarization layer; a light emitting element on the first reflection electrode; and a second reflection electrode which is disposed so as to cover the light emitting element. The light emitting element is disposed on any one of the first top surface and the second top surface. Accordingly, the first reflection electrode is disposed on the inclined surface to more easily extract light emitted from the light emitting element to the outside.

Other detailed matters of the exemplary embodiments are included in the detailed description and the drawings.

According to the present disclosure, a high resolution display device which includes an inorganic light emitting element with excellent luminous efficiency to display an image with a high efficiency and a high luminance at a low power may be implemented.

According to the present disclosure, reflection electrodes are formed above and below a light emitting element and a light conversion layer to improve a light conversion efficiency and a light extraction efficiency.

According to the present disclosure, an inclined surface is formed in an area in which the light conversion layer is disposed to easily control the thickness of the light conversion layer.

According to the present disclosure, an irregular structure is formed in an area where light is released to improve the light extraction efficiency.

The effects according to the present disclosure are not limited to the contents exemplified above, and more various effects are included in the present specification.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is an enlarged plan view of a display device according to an exemplary embodiment of the present disclosure;

FIG. 4 is a cross-sectional view of a sub pixel of a display device according to an exemplary embodiment of the present disclosure;

FIGS. 5A and 5B are views illustrating a placement relationship of a light emitting element, a first reflection electrode, a second reflection electrode, and a bank in each of display devices according to a comparative embodiment and an exemplary embodiment;

FIG. 6 is a graph illustrating a light conversion efficiency according to an angle in each of display devices according to a comparative embodiment and an exemplary embodiment;

FIG. 7 is a graph illustrating a light conversion efficiency according to a thickness of a light conversion layer;

FIG. 8 is an enlarged plan view of a display device according to another exemplary embodiment of the present disclosure;

FIG. 9 is an enlarged plan view of a display device according to still another exemplary embodiment of the present disclosure;

FIG. 10 is a cross-sectional view of a display device according to still another exemplary embodiment of the present disclosure;

FIG. 11 is an enlarged plan view of a display device according to still another exemplary embodiment of the present disclosure; and

FIG. 12 is a cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or layer or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiments of the present disclosure will be described in detail with reference to accompanying drawings.

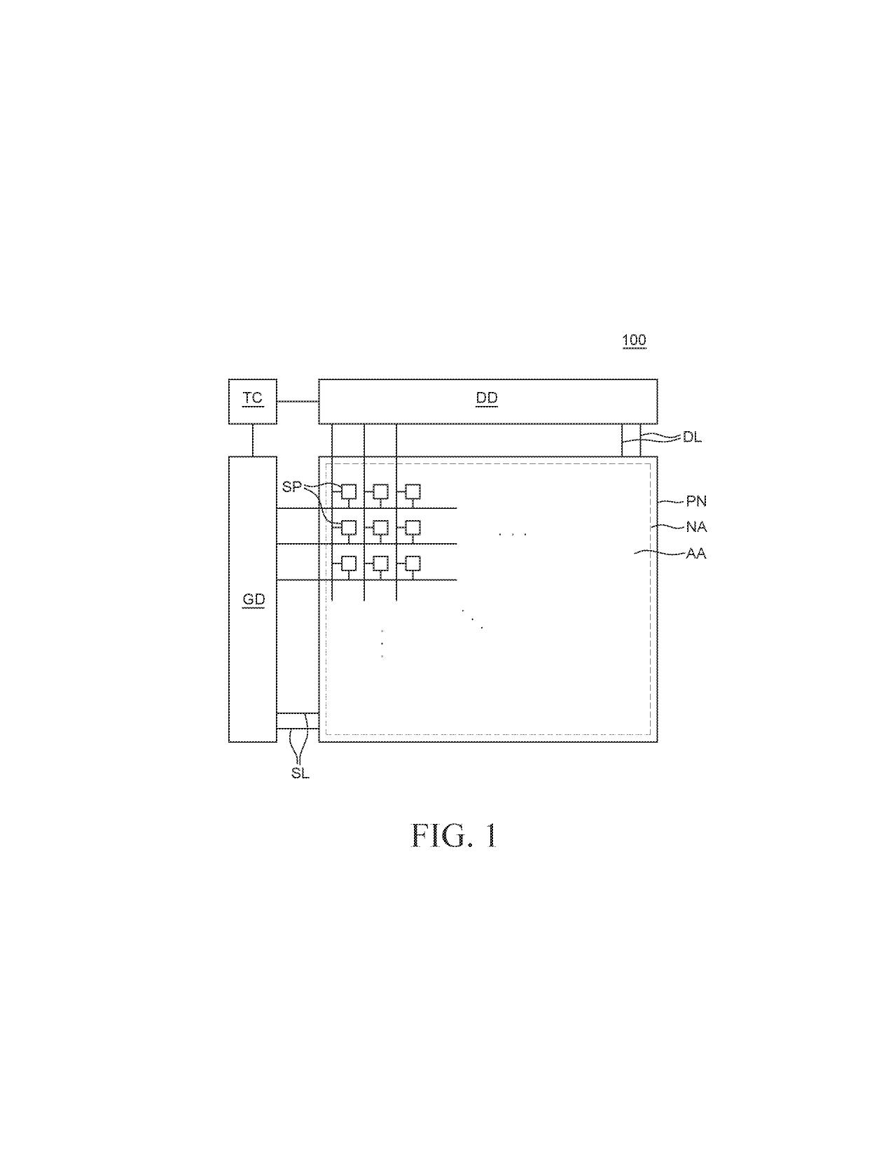

FIG. 1 is a schematic diagram of a display device according to an exemplary embodiment of the present disclosure. In FIG. 1, for the convenience of description, among various components of the display device 100, a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of gate drivers GD and the placement thereof are not limited thereto.

The data driver DD supplies a data voltage to a plurality of data lines DL according to a plurality of data control signals and image data supplied from the timing controller TC. The data driver DD may convert the image data into a data voltage using a reference gamma voltage and supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP may be formed at intersections of the scan lines SL and the data lines DL.

In the display panel PN, an active area AA and a non-active area NA may be defined.

The active area AA is an area in which images are displayed in the display device 100. In the active area AA, a plurality of sub pixels SP which configure a plurality of pixels PX and a pixel circuit for driving the plurality of sub pixels SP may be disposed. The plurality of sub pixels SP is a minimum unit which configures the active area AA and n sub pixels SP may form one pixel PX. In each of the plurality of sub pixels SP, a thin film transistor for driving a plurality of light emitting elements 120 may be disposed. The plurality of light emitting elements 120 may be defined in different ways depending on the type of the display panel PN. For example, when the display panel PN is an inorganic light emitting display panel PN, the light emitting element 120 may be a light emitting diode (LED) or a micro light emitting diode (micro LED).

In the active area AA, a plurality of signal lines which transmit various signals to the plurality of sub pixels SP is disposed. For example, the plurality of signal lines may include a plurality of data lines DL which supply a data voltage to each of the plurality of sub pixels SP and a plurality of scan lines SL which supply a scan signal to each of the plurality of sub pixels SP. The plurality of scan lines SL extend to one direction in the active area AA to be connected to the plurality of sub pixels SP and the plurality of data lines DL extend to a direction different from the one direction in the active area AA to be connected to the plurality of sub pixels SP. In addition, in the active area AA, a low potential power line PL and a high potential power line PL may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed.

In the meantime, the non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board. The display panel PN may be electrically connected to the data driver DD and the timing controller TC by bonding the flexible film and the printed circuit board to the pad electrode formed in the non-active area NA of the display panel PN.

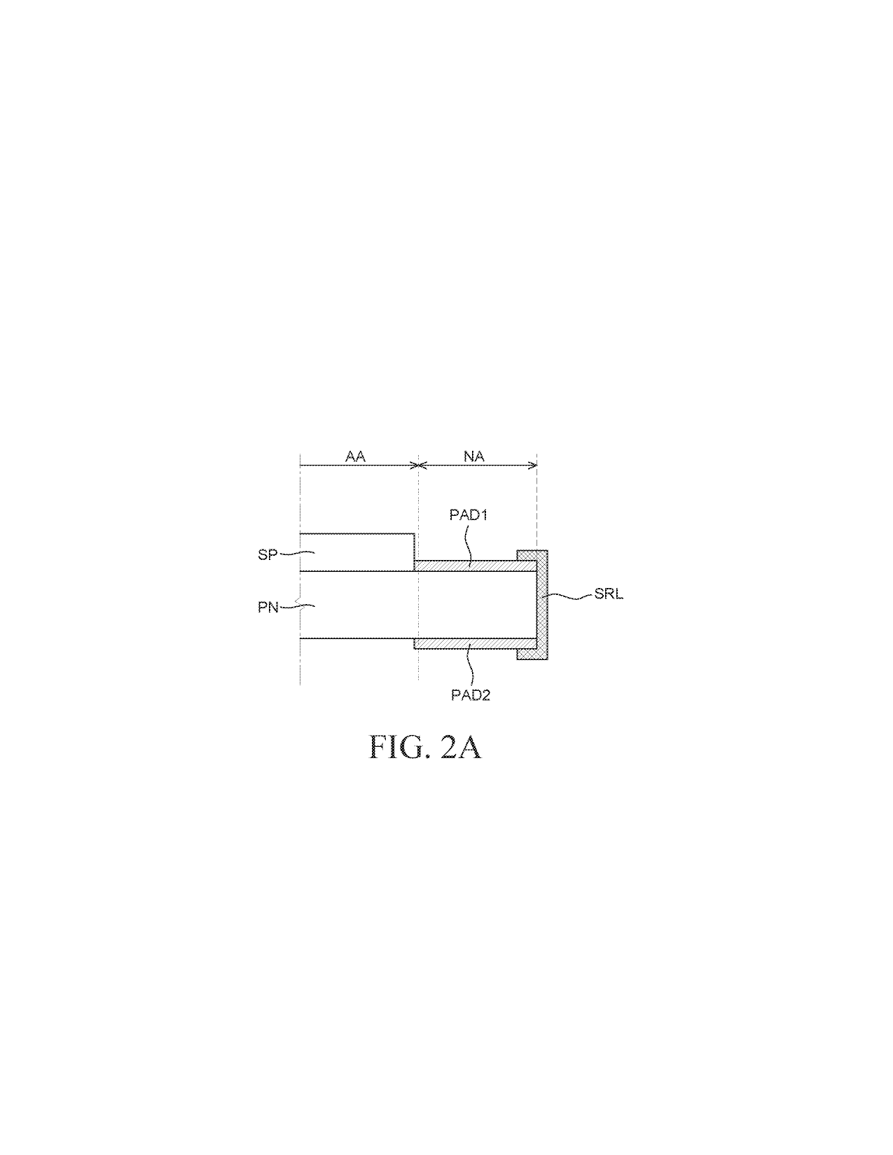

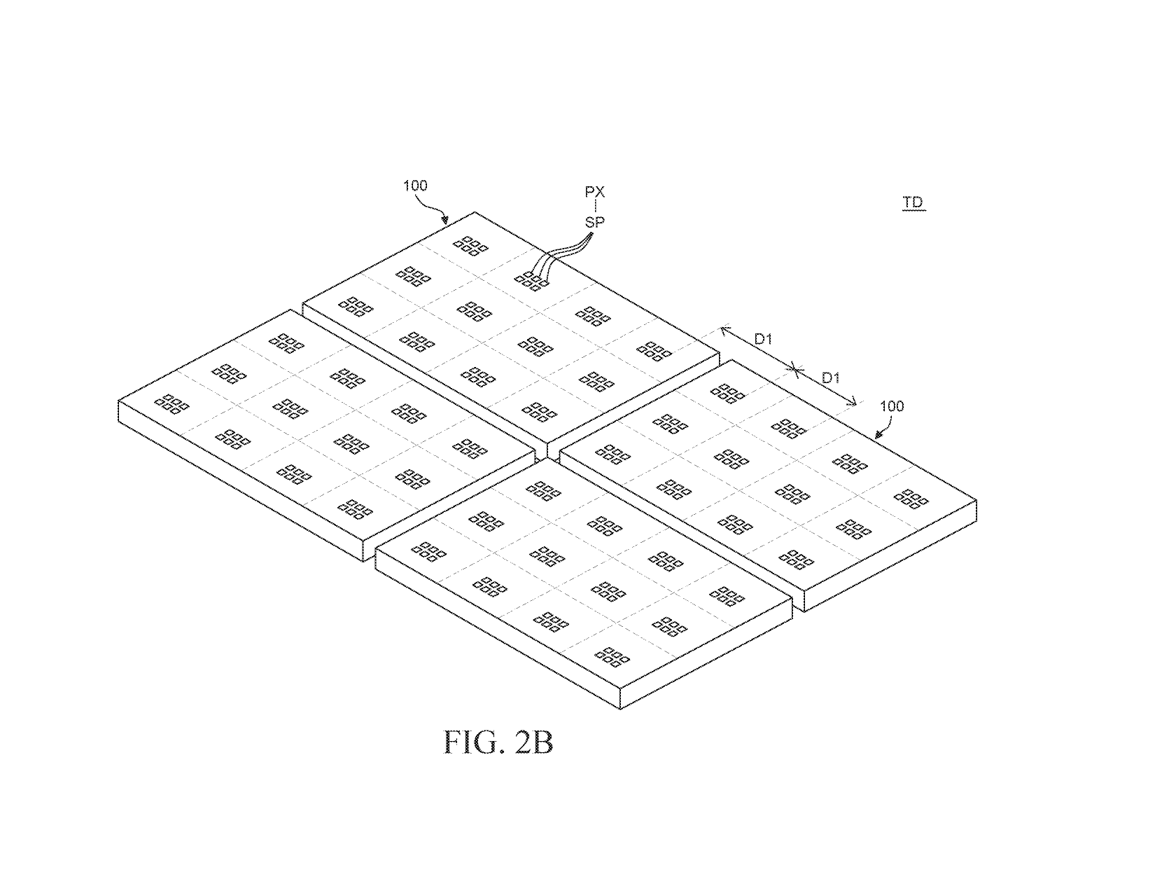

As another example, when the gate driver GD is mounted in the active area AA in the GIA manner and a side line SRL which connects the signal line on the front surface of the display panel PN to the pad electrode on a rear surface of the display panel PN is formed to bond the flexible film and the printed circuit board onto a rear surface of the display panel PN, the non-active area NA on the front surface of the display panel PN may be minimized. Therefore, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display device according to an exemplary embodiment of the present disclosure. FIG. 2B is a perspective view of a tiling display device according to an exemplary embodiment of the present disclosure.

In the non-active area NA of the display panel PN, a plurality of pad electrodes for transmitting various signals to the plurality of sub pixels SP are disposed. For example, in a non-active area NA on the front surface of the display panel PN, a first pad electrode PAD1 which transmits a signal to the plurality of sub pixels SP is disposed. In a non-active area NA on the rear surface of the display panel PN, a second pad electrode PAD2 which is electrically connected to a driving component, such as a flexible film and the printed circuit board, is disposed.

In this case, even though it is not illustrated in the drawing, various signal lines connected to the plurality of sub pixels SP, for example, a scan line SL or a data line DL extend from the active area AA to the non-active area NA to be electrically connected to the first pad electrode PAD1.

The side line SRL is disposed along a side surface of the display panel PN. The side line SRL may electrically connect the first pad electrode PAD1 on the front surface of the display panel PN and the second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path is formed from the front surface of the display panel PN to the side surface and the rear surface to minimize an area of the non-active area NA on the front surface of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, the interval of the pixels PX between the display devices 100 is constantly configured to minimize the seam area.

However, FIGS. 2A and 2B are illustrative so that the display device 100 according to the exemplary embodiment of the present disclosure may be a general display device with a bezel, but is not limited thereto.

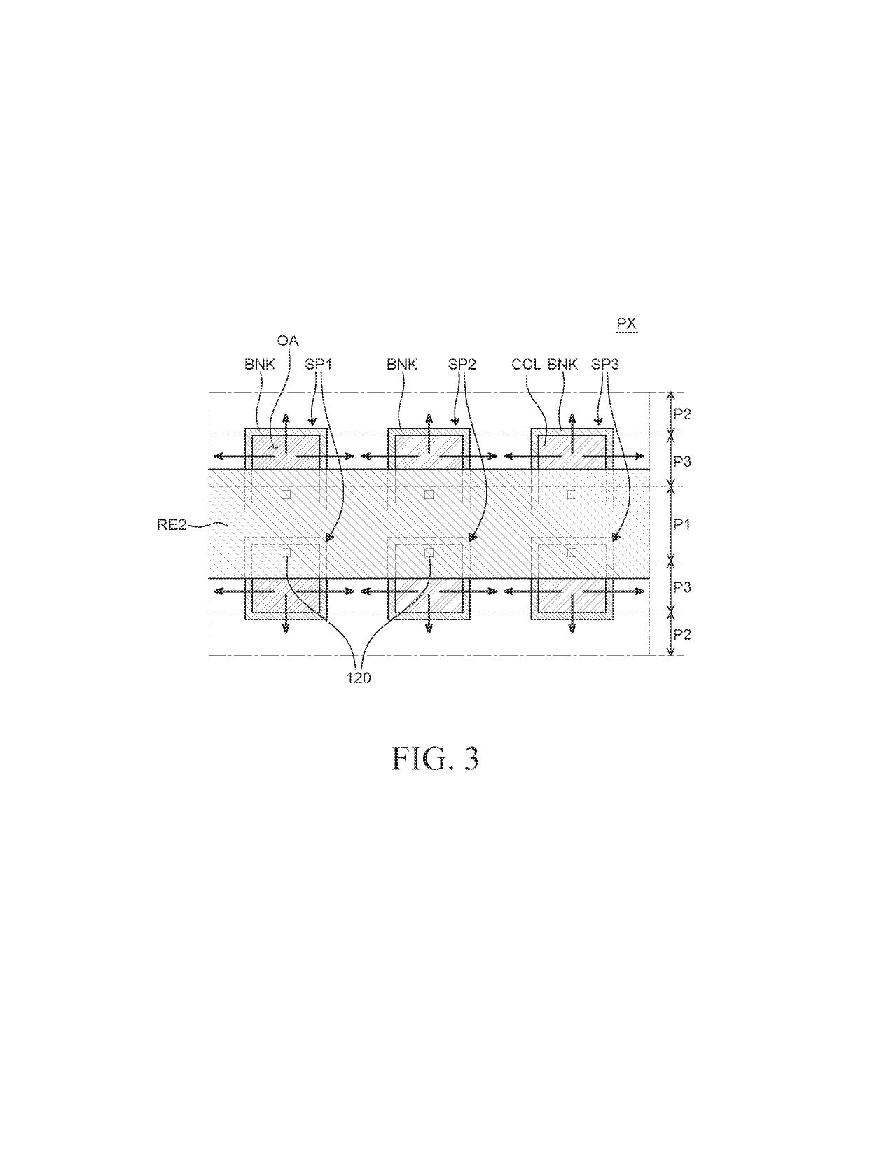

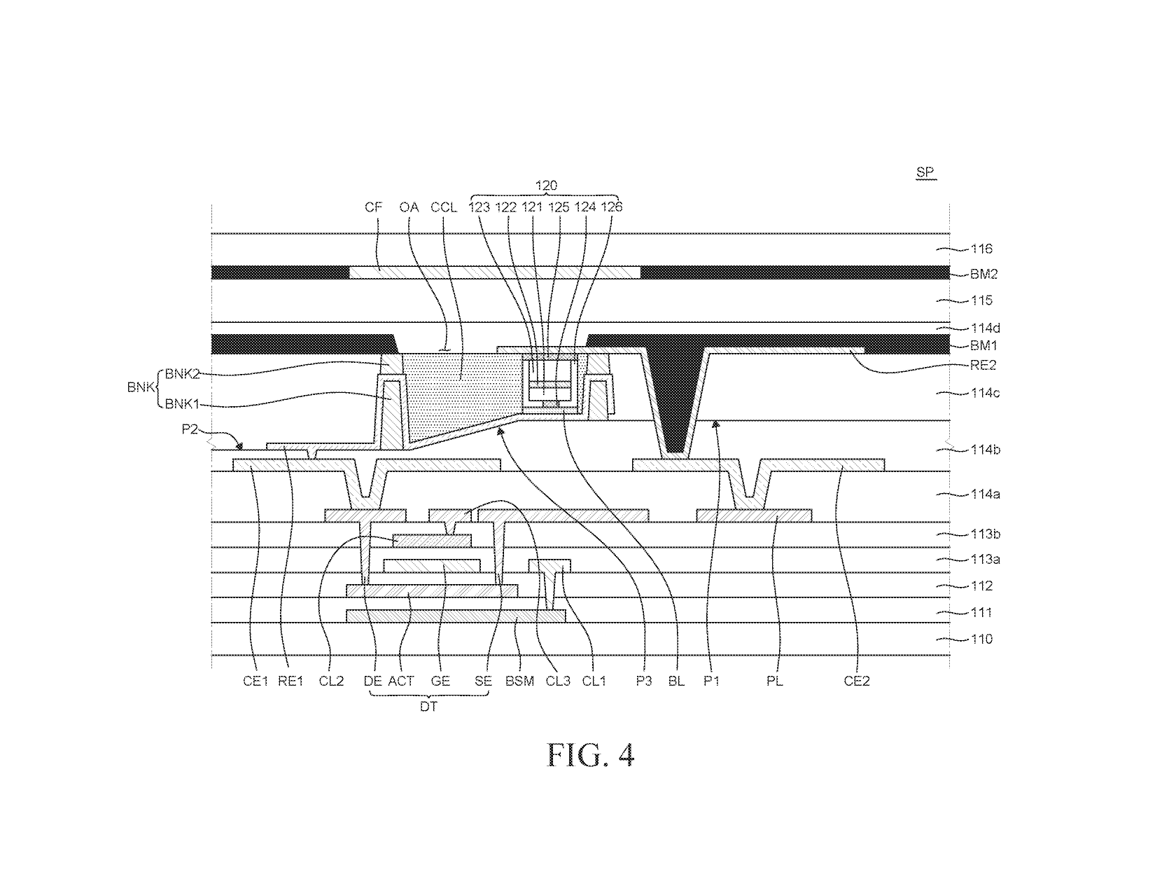

Hereinafter, a sub pixel SP of a display panel PN of a display device 100 according to an exemplary embodiment of the present disclosure will be described in more detail with reference to FIGS. 3 and 4.

FIG. 3 is an enlarged plan view of a display device according to an exemplary embodiment of the present disclosure. FIG. 4 is a cross-sectional view of a sub pixel of a display device according to an exemplary embodiment of the present disclosure. In FIG. 3, for the convenience of description, the plurality of light emitting elements 120, the plurality of sub pixels SP, a bank BNK, and a plurality of light conversion layers CCL are illustrated. The arrow in FIG. 3 indicates a direction in which light is released from each sub pixel SP.

Referring to FIGS. 3 and 4, the plurality of sub pixels SP are disposed in the active area AA. Each of the plurality of sub pixels SP may include a light emitting element 120 and independently emit light. The plurality of sub pixels SP may be disposed in a matrix by forming a plurality of rows and a plurality of columns, but the exemplary embodiments of the present disclosure are not limited thereto.

One pixel PX may include a plurality of sub pixels SP and the plurality of sub pixels SP may include a first sub pixel SP1, a second sub pixel SP2, and a third sub pixel SP3. For example, one pixel PX may include one pair of first sub pixels SP1, one pair of second sub pixels SP2, and one pair of third sub pixels SP3. For example, any one of the first sub pixel SP1, the second sub pixel SP2, and the third sub pixel SP3 may be a red sub pixel SP, another may be a green sub pixel SP, and the third may be a blue sub pixel SP. For example, the first sub pixel SP1 may be a blue sub pixel SP, a second sub pixel SP2 may be a red sub pixel SP, and a third sub pixel SP3 may be a green sub pixel SP. The types of the plurality of sub pixels SP are illustrative, but the exemplary embodiments of the present disclosure are not limited thereto.

Referring to FIG. 4, the first substrate 110 may be a member which supports other components of the display device 100 and may be an insulating substrate. For example, the first substrate 110 may be formed of glass or resin. Further, the first substrate 110 may be formed of polymer or plastic and in some exemplary embodiments, the first substrate 110 may be formed of a plastic material having flexibility. A plurality of pixels PX each including a plurality of sub pixels SP is formed on the first substrate 110 to display images.

A light shielding layer BSM is disposed on the first substrate 110 in each of the plurality of sub pixels SP. The light shielding layer BSM blocks light which is incident onto the active layer ACT of the driving transistor DT to minimize or at least reduce a leakage current. For example, the light shielding layer BSM is disposed below the active layer ACT of the driving transistor DT to block light incident onto the active layer ACT. If light is irradiated onto the active layer ACT, leakage current is generated, which degrades the reliability of the driving transistor DT. Accordingly, the light shielding layer BSM which blocks the light is disposed on the first substrate 110 to improve the reliability of the driving transistor DT. The light shielding layer BSM may be configured by an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the first substrate 110 and the light shielding layer BSM. The buffer layer 111 is disposed so as to cover one surface of the first substrate 110 to reduce permeation of moisture or impurities through the first substrate 110. The buffer layer 111 may be configured by a single layer or a double layer of silicon oxide (SiOx) or silicon nitride (SiNx), but is not limited thereto. The buffer layer 111 may be omitted depending on a type of the first substrate 110 or a type of transistor, but is not limited thereto.

The driving transistor DT is disposed on the buffer layer 111 in each of the plurality of sub pixels SP. The driving transistor DT includes an active layer ACT, a gate electrode GE, a source electrode SE, and a drain electrode DE. In the meantime, even though it is not illustrated in the drawing, in each of the plurality of sub pixels SP, other components, such as a switching transistor, a sensing transistor, an emission control transistor, and a storage capacitor may be further disposed, in addition to the driving transistor DT.

The active layer ACT of the driving transistor DT is disposed on the buffer layer 111. The active layer ACT may be disposed so as to overlap the light shielding layer BSM. The active layer ACT may be formed of a semiconductor material, such as an oxide semiconductor, amorphous silicon, or polysilicon, but is not limited thereto. Further, even though it is not illustrated in the drawings, active layers ACT of another transistors, such as a switching transistor, a sensing transistor, and an emission control transistor, may also be formed of a semiconductor material, such as an oxide semiconductor, amorphous silicon, or polysilicon, but are not limited thereto. The active layers ACT of the driving transistor DT, the switching transistor, the sensing transistor, and the emission control transistor may be formed of the same material, or formed of different materials.

A gate insulating layer 112 is disposed on the active layer ACT. The gate insulating layer 112 is a layer for insulating the active layer ACT from the gate electrode GE. For example, the gate insulating layer 112 may be configured by a single layer or a double layer of silicon oxide (SiOx) or silicon nitride (SiNx), but is not limited thereto. In the meantime, even though in the drawing, it is illustrated that the gate insulating layer 112 is disposed only below the gate electrode GE, the gate insulating layer 112 may be disposed on the front surface of the first substrate 110, but is not limited thereto.

The gate electrode GE is disposed on the gate insulating layer 112. The gate electrode GE may be disposed so as to overlap the active layer ACT. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

A first interlayer insulating layer 113a and a second interlayer insulating layer 113b are disposed on the gate electrode GE. In the first interlayer insulating layer 113a and the second interlayer insulating layer 113b, contact holes through which the source electrode SE and the drain electrode DE are connected to the active layer ACT are formed. The first interlayer insulating layer 113a and the second interlayer insulating layer 113b are insulating layers which protect components therebelow and may be configured by a single layer or a double layer of silicon oxide (SiOx) or silicon nitride (SiNx), but are not limited thereto.

The source electrode SE and the drain electrode DE are disposed on the second interlayer insulating layer 113b. The source electrode SE and the drain electrode DE may be electrically connected to the active layer ACT through contact holes formed in the first interlayer insulating layer 113a, the second interlayer insulating layer 113b, and the gate insulating layer 112. Any one of the source electrode SE and the drain electrode DE may be electrically connected to the light emitting element 120. For example, any one of the source electrode SE and the drain electrode DE may supply a driving current to the light emitting element 120 through a first connection electrode CE1 and a first reflection electrode RE1. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

A first conductive layer CL1 is disposed on the gate insulating layer 112. The first conductive layer CL1 is an electrode which applies a constant voltage to the light shielding layer BSM and may be electrically connected to the light shielding layer BSM through contact holes of the gate insulating layer 112 and the buffer layer 111. For example, the light shielding layer BSM is connected to the first conductive layer CL1 so as not to be operated as a floating gate and fluctuation of a threshold voltage of the driving transistor DT due to the floated light shielding layer BSM may be suppressed. The first conductive layer CL1 may be configured by a conductive material, such as copper (Cu), aluminum (Al), molybdenum (Mo), nickel (Ni), titanium (Ti), chrome (Cr), or an alloy thereof, but is not limited thereto.

A second conductive layer CL2 is disposed on the first interlayer insulating layer 113a and a third conductive layer CL3 which is electrically connected to the second conductive layer CL2 is disposed on the second interlayer insulating layer 113b. The second conductive layer CL2 and the third conductive layer CL3 are disposed so as to overlap a gate electrode GE of a driving transistor DT to form a capacitor with the gate electrode GE of the driving transistor DT. Accordingly, various conductive layers, such as the second conductive layer CL2 and the third conductive layer CL3, are disposed on the first substrate 110 to form a capacitor. The second conductive layer CL2 and the third conductive layer CL3 may be configured by a conductive material, such as copper (Cu), aluminum (Al), molybdenum (Mo), nickel (Ni), titanium (Ti), chrome (Cr), or an alloy thereof, but is not limited thereto.

A power line PL is disposed on the second interlayer insulting layer 113b. The power line PL may be configured to transmit a power voltage to the light emitting elements 120 of the plurality of sub pixels SP. The power line PL may be configured by a conductive material, and for example, may be configured of copper (Cu), aluminum (Al), molybdenum (Mo), nickel (Ni), titanium (Ti), chrome (Cr), or an alloy thereof, but is not limited thereto. The power line PL may be electrically connected to the plurality of light emitting elements 120 through the second connection electrode CE2 and a second reflection electrode RE2 to be described below. The power line PL may be configured as any one of a low potential power line PL or a high potential power line PL according to the configuration of the pixel circuit.

A first planarization layer 114a is disposed on the driving transistor DT, the power line PL, and the second interlayer insulating layer 113b. The first planarization layer 114a may planarize an upper portion of the pixel circuit including the driving transistor DT. The first planarization layer 114a may be configured by a single layer or a double layer, and for example, may be configured by benzocyclobutene or an acrylic organic material, but is not limited thereto.

Next, a plurality of connection electrodes CE is disposed on the first planarization layer 114a. The plurality of connection electrodes CE is electrodes which connect the driving transistor DT and the power line PL to the light emitting element 120. The plurality of connection electrodes CE includes a first connection electrode CE1 and a second connection electrode CE2. The first connection electrode CE1 may be electrically connected to the driving transistor DT and the second connection electrode CE2 may be electrically connected to the power line PL. The plurality of connection electrodes CE may be configured by a conductive material, and for example, may be configured of copper (Cu), aluminum (Al), molybdenum (Mo), nickel (Ni), titanium (Ti), chrome (Cr), or an alloy thereof, but is not limited thereto.

The second planarization layer 114b is disposed on the plurality of connection electrodes CE. The second planarization layer 114b may be configured by a single layer or a double layer, and for example, may be configured by benzocyclobutene or an acrylic organic material, but is not limited thereto.

The second planarization layer 114b may have an entirely flat top surface. The second planarization layer 114b may partially have an inclined surface P3 in each of the plurality of sub pixels SP and for example, may have an inclined surface P3 in at least a part of an area overlapping the first reflection electrode RE1. For example, the second planarization layer 114b may include a first top surface P1, an inclined surface P3 which obliquely extends from the first top surface P1, and a second top surface P2 which extends from the inclined surface P3 and is lower than the first top surface P1. The inclined surface P3 may be disposed so as to overlap the light conversion layer CCL of the plurality of sub pixels SP and each of the first top surface P1 and the second top surface P2 may be disposed between an inclined surface P3 of one sub pixel SP and an inclined surface P3 of a sub pixel SP adjacent to the one sub pixel SP. The inclined surface P3 is formed in at least a part of the top surface of the second planarization layer 114b to increase the thickness of the light conversion layer CCL and improve the light conversion efficiency of the light emitting element 120.

In each of the plurality of sub pixels SP, a first bank BNK1 of the bank BNK is disposed on the second planarization layer 114b. The first bank BNK1 may be disposed so as to enclose the light emitting element 120 and the light conversion layer CCL. For example, referring to FIG. 3, the first bank BNK1 disposed in each of the plurality of sub pixels SP may be formed to have a closed loop shape which encloses the light emitting element 120 and the light conversion layer CCL. For example, a planar shape of the first bank BNK1 may be various shapes, such as a rectangular shape or a circular shape.

The first bank BNK1 may minimize or at least reduce color mixture between the plurality of sub pixels SP. The first bank BNK1 may be formed of an insulating material. Further, the first bank BNK1 further includes a black material to block wiring lines which may be visible through the active area AA. For example, the first bank BNK1 may be formed of a carbon-based mixture and specifically, include carbon black. Further, the first bank BNK1 may be formed by dispersing various light scattering materials in a transparent insulating material or an opaque insulating material. For example, the first bank BNK1 includes a light scattering material, such as titanium dioxide (TiO2) to change a path of some light which is directed to the side direction of the light emitting element 120, among light emitted from the light emitting element 120 to an upper direction of the light emitting element 120 and improve the light extraction efficiency of the light emitting element 120.

The first bank BNK1 may be formed by a part disposed on the first top surface P1, another part disposed on the second top surface P2, and the remaining part which connects the part and another part. At least a part of the light conversion layer CCL may be disposed on the inclined surface P3 and the first bank BNK1 which encloses the light emitting element 120 and the light conversion layer CCL may be disposed so as to enclose the inclined surface P3. At this time, a thickness of another part of the first bank BNK1 disposed on the second top surface P2 may be larger than a thickness of the part of the first bank BNK1 disposed on the first top surface P1. The thickness of the part of the first bank BNK1 disposed on the second top surface P2 is formed to be large to constantly maintain a height of the top surface of the first bank BNK1 without being limited to the height difference between the first top surface P1 and the second top surface P2.

In each of the plurality of sub pixels SP, the first reflection electrode RE1 is disposed on the second planarization layer 114b and the first bank BNK1. The first reflection electrode RE1 reflects light emitted from the light emitting element 120 to the top of the first substrate 110 and electrically connects the light emitting element 120 and the driving transistor DT. The first reflection electrode RE1 may be disposed so as to cover the first bank BNK1 and the inclined surface P3. For example, the first reflection electrode RE1 may be disposed so as to cover at least the top surface and the inner surface of the first bank BNK1. The first reflection electrode RE1 may be in contact with a top surface and a side surface of the first bank BNK1. The first reflection electrode RE1 may be disposed so as to cover the overall top surface of the second planarization layer 114b located in the inside of the first bank BNK1 having a closed loop shape. The first reflection electrode RE1 may be disposed so as to cover the inclined surface P3 located in the inside of the first bank BNK1. A part of the first reflection electrode RE1 extends to the outside of the first bank BNK1 and may be electrically connected to the first connection electrode CE1 through a contact hole of the second planarization layer 114b.

The first reflection electrodes RE1 may include various conductive layers in consideration of a light reflection efficiency and a resistance. For example, the first reflection electrode RE1 may include an opaque conductive layer, such as silver (Ag), aluminum (Al), molybdenum (Mo), titanium (Ti), or an alloy thereof, and a transparent conductive layer, such as indium tin oxide (ITO) together, but the configuration of the first reflection electrode RE1 is not limited thereto.

In each of the plurality of sub pixels SP, the second bank BNK2 is disposed on the first reflection electrode RE1 and the first bank BNK1. The second bank BNK2 may be disposed above the first bank BNK1 so as to overlap the first bank BNK1. The first reflection electrode RE1 may be disposed between the first bank BNK1 and the second bank BNK2. The second bank BNK2 may be formed with the same planar shape as the first bank BNK1. Similar to the first bank BNK1, the second bank BNK2 may be formed with a closed loop shape which encloses the light conversion layer CCL and the light emitting element 120. The second bank BNK2 may be formed with the same material as the first bank BNK1 and for example, may be formed of any one of an insulating material including a black material or an insulating material including a light scattering material, but the material of the second bank BNK2 is not limited thereto.

A bonding layer BL is disposed on the first reflection electrode RE1 in each of the plurality of sub pixels SP. The bonding layer BL may be a conductive adhesion member which electrically connects the light emitting element 120 and the first reflection electrode RE1 while fixing the light emitting elements 120 onto the first reflection electrode RE1. The bonding layer BL may have conductivity to electrically connect the first reflection electrode RE1 and the plurality of light emitting elements 120. The bonding layer BL may have adhesiveness to fix the plurality of light emitting elements 120 to the first reflection electrode RE1. For example, the bonding layer BL may be formed of a material including conductive particles, such as indium and may be an organic layer including conductive particles such as carbon, but is not limited thereto. In this case, the bonding layer BL may be formed of a material on which the photolithography process may be performed and a thickness or a placement area of the bonding layer BL may be easily controlled by the photolithography process.

The light emitting element 120 is disposed on the bonding layer BL in each of the plurality of sub pixels SP. For example, the light emitting element 120 may be disposed on a part of the first reflection electrode RE1 overlapping the first top surface P1. The light emitting element 120 may be disposed in an area between the inclined surface P3 and the first bank BNK1. The light emitting element 120 may be disposed to be biased to one side of the area enclosed by the first bank BNK1. The light emitting element 120 may be any one of a light-emitting element (LED) or a micro light-emitting element (micro LED), but the exemplary embodiments of the present disclosure are not limited thereto. The light emitting element 120 includes a first semiconductor layer 121, an emission layer 122, a second semiconductor layer 123, a first electrode 124, a second electrode 125, and a protection film 126.

First, the first semiconductor layer 121 is disposed on the first reflection electrode RE1 and the second semiconductor layer 123 is disposed on the first semiconductor layer 121. The first semiconductor layer 121 and the second semiconductor layer 123 may be semiconductor layers doped with n-type and p-type impurities. For example, the first semiconductor layer 121 and the second semiconductor layer 123 may be layers formed by doping p-type and n-type impurities into a material, such as gallium nitride (GaN), indium aluminum phosphide (InAlP), or gallium arsenide (GaAs). The p-type impurity may be magnesium (Mg), zinc (Zn), and beryllium (Be), and the n-type impurity may be silicon (Si), germanium, and tin (Sn), but are not limited thereto.

The emission layer 122 is disposed between the first semiconductor layer 121 and the second semiconductor layer 123. The emission layer 122 may emit light based on a driving current supplied to the light emitting element 120. For example, the emission layer 122 may emit blue light and the light emitting element 120 may be a blue light emitting element. The emission layer 122 may be formed by a single layer or a multi-quantum well (MQW) structure, and for example, may be formed of indium gallium nitride (InGaN) or gallium nitride (GaN), but is not limited thereto.

The first electrode 124 is disposed below the first semiconductor layer 121. The first electrode 124 may be in contact with a bottom surface of the first semiconductor layer 121. The first electrode 124 is an electrode for electrically connecting the light emitting element 120 to the first reflection electrode RE1 and the driving transistor DT. The light emitting element 120 may be electrically connected to the driving transistor DT through the first electrode 124, the first reflection electrode RE1, and the first connection electrode CE1. The first electrode 124 may be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, it is not limited thereto.

The second electrode 125 is disposed on the second semiconductor layer 123. The second electrode 125 may be in contact with the top surface of the second semiconductor layer 123. The second electrode 125 is an electrode for electrically connecting the light emitting element 120 and the power line PL. The light emitting element 120 may be electrically connected to the power line PL through the second electrode 125, the second reflection electrode RE2, and the second connection electrode CE2. The second electrode 125 may be formed of a transparent conductive material, such as indium tin oxide (ITO) or indium zinc oxide (IZO), but is not limited thereto.

The protection film 126 which encloses the first semiconductor layer 121, the emission layer 122, and the second semiconductor layer 123 is disposed. The protection film 126 may protect the first semiconductor layer 121, the emission layer 122, and the second semiconductor layer 123. The protection film 126 may be disposed so as to enclose a side surface and a part of a bottom surface of the first semiconductor layer 121, a side surface of the emission layer 122, and a side surface of the second semiconductor layer 123. The first electrode 124 and the second electrode 125 are exposed from the protection film 126 to be connected to the first reflection electrode RE1 and the second reflection electrode RE2. For example, the protection film 126 may be formed of an insulating material, such as silicon oxide (SiOx) or silicon nitride (SiNx), but is not limited thereto.

The light conversion layer CCL is disposed in an area inside the first bank BNK1 and the second bank BNK2. The light conversion layer CCL may be filled in an area on the inclined surface P3 enclosed by the first bank BNK1 and the second bank BNK2. A side surface of the light conversion layer CCL may be in contact with the first reflection electrode RE1 and the second bank BNK2. The light conversion layer CCL may be disposed so as to enclose the side surface of the light emitting element 120. The light conversion layer CCL includes a light conversion material, such as a quantum dot, a nano fluorescent material, or an organic fluorescent material to convert light emitted from the light emitting element 120 into light of various colors. For example, the light conversion layer CCL may convert light from the light emitting element 120 into light of various colors, such as red light, green light, and blue light. For example, when the light emitting element 120 emits blue light, the light conversion layer CCL may include a green light conversion layer CCL and a red light conversion layer CCL. For example, when the light emitting element 120 emits light in an ultraviolet wavelength area, the light conversion layer CCL may include a red light conversion layer CCL, a green light conversion layer CCL, and a blue light conversion layer CCL.

Next, a third planarization layer 114c is disposed on the second planarization layer 114b. The third planarization layer 114c may be disposed in an area between the plurality of first banks BNK1 and an area between the plurality of second banks BNK2. The third planarization layer 114c is disposed in an area at the outside of the first bank BNK1 and an area at the outside of the second bank BNK2 to cover a first top surface P1 or a second top surface P2 of the second planarization layer 114b. The third planarization layer 114c may be configured by a single layer or a double layer, and for example, may be configured by benzocyclobutene or an acrylic organic material, but is not limited thereto.

A second reflection electrode RE2 is disposed on the third planarization layer 114c and the second bank BNK2. The second reflection electrode RE2 reflects the light emitted from the light emitting element 120 to the top of the first substrate 110 and electrically connects the light emitting element 120 and the power line PL. The second reflection electrode RE2 may be electrically connected to the second connection electrode CE2 and the power line PL through contact holes formed in the third planarization layer 114c and the second planarization layer 114b. The second reflection electrode RE2 is in contact with the second electrode 125 above the light emitting element 120 exposed from the light conversion layer CCL to be electrically connected to the light emitting element 120. The light emitting element 120 may be electrically connected to the power line PL through the second reflection electrode RE2 and the second connection electrode CE2.

The second reflection electrodes RE2 may include various conductive layers in consideration of a light reflection efficiency and a resistance. For example, the second reflection electrodes RE2 may be formed of an opaque conductive layer, such as silver (Ag), aluminum (Al), molybdenum (Mo), titanium (Ti), or an alloy thereof. The second reflection electrode RE2 may further include an opaque conductive layer and a transparent conductive layer, such as indium tin oxide (ITO), but a configuration of the second reflection electrode RE2 is not limited thereto.

In the meantime, the second reflection electrode RE2 may be disposed so as to cover a part of the light conversion layer CCL. The light emitting element 120 is disposed between the first bank BNK1 and the inclined surface P3 and the second reflection electrode RE2 may be disposed to extend from the first top surface P1 toward the light emitting element 120 and the inclined surface P3. The second reflection electrode RE2 may be disposed so as to cover an upper portion of the light emitting element 120 to also cover a part of the light conversion layer CCL adjacent to the light emitting element 120. For example, the second reflection electrode RE2 may be disposed so as to cover an area on the first top surface P1 and a part of the light conversion layer CCL disposed in a partial area of the inclined surface P3 adjacent to the first top surface P1. The remaining portion of the light conversion layer CCL disposed on the other area of the inclined surface P3 may be exposed from the second reflection electrode RE2. Therefore, an area which is exposed from the second reflection electrode RE2 to release light may be defined as an open area OA.

The light emitting element 120 is disposed on the first top surface P1 in an area in the first bank BNK1 and light emitted from the light emitting element 120 may be reflected toward the light conversion layer CCL on the inclined surface P3 by the second reflection electrode RE2 and the first reflection electrode RE1. The light conversion layer CCL on the inclined surface P3 has a relatively larger thickness than the light conversion layer CCL on the first top surface P1 so that light may be more easily converted by the light conversion layer CCL on the inclined surface P3. Accordingly, the light emitting element 120 is disposed on the first top surface P1 and light emitted from the light emitting element 120 is reflected toward the light conversion layer CCL on the inclined surface P3 by the first reflection electrode RE1 and the second reflection electrode RE2 to improve an overall light conversion efficiency.

Further, light which is converted by the light conversion layer CCL may be directed to the outside of the display device 100 through the open area OA exposed from the second reflection electrode RE2. Light which is converted by the light conversion layer CCL is reflected between the first reflection electrode RE1 and the second reflection electrode RE2 to change the light path and may be released to the outside of the display device 100 through an open area OA in which the second reflection electrode RE2 is not formed.

In the meantime, referring to FIG. 3, the second reflection electrode RE2 may be disposed in each of the plurality of sub pixels SP and one second reflection electrode RE2 may be disposed in several sub pixels SP. For example, the second reflection electrode RE2 is an electrode which commonly transmits the power voltage to the plurality of light emitting elements 120 so that in some sub pixels SP, the second reflection electrode RE2 is shared.

The plurality of sub pixels SP which shares one second reflection electrode RE2 are symmetrically disposed with respect to the second reflection electrode RE2 to suppress degradation of the viewing angle characteristic. For example, one second reflection electrode RE2 may be disposed between one pair of first sub pixels SP1 which is adjacent to each other in a column direction, between one pair of second sub pixels SP2 which is adjacent to each other in a column direction, and between one pair of third sub pixels SP3 which is adjacent to each other in a column direction. For example, the second reflection electrode RE2 covers a lower area of one first sub pixel SP1 and an upper area of the other first sub pixel SP1, between one pair of first sub pixels SP1. In this case, in the open area OA of one first sub pixel SP1, light may be released to an upper direction, a left direction, and a right direction and in the open area OA of the other first sub pixel SP1, light may be released to a lower direction, the left direction, and the right direction. In this case, in one pair of first sub pixels SP1, amounts of light released to the left direction and the right direction are implemented to be substantially the same so that the luminance deviation according to the viewing angle in the left direction and the right direction may be minimized. Further, in one pair of first sub pixels SP1, an amount of light released to the upper direction and an amount of light released to the lower direction are implemented to substantially the same so that the luminance deviation according to the viewing angle in the upper direction and the lower direction may be minimized. Accordingly, the open areas OA of the plurality of sub pixels SP may be symmetrically disposed with respect to the second reflection electrode RE2.

Next, a first black matrix BM1 is disposed on the third planarization layer 114c and the second reflection electrode RE2. The first black matrix BM1 may be disposed in the remaining area excluding an area in which the light conversion layer CCL is disposed. The first black matrix BM1 may shield light of the plurality of sub pixels SP so as not to cause the color mixture. Further, the first black matrix BM1 absorbs light incident to the display device 100 from the outside to minimize or at least reduce degradation of visibility due to external light which is reflected by the configuration in the display device 100. For example, the first black matrix BM1 includes a black component and may be formed of an opaque resin including a dye, but is not limited thereto.

A fourth planarization layer 114d is disposed on the first black matrix BM1. The fourth planarization layer 114d may provide a flat surface on the first black matrix BM1. The fourth planarization layer 114d may be configured by a single layer or a double layer, and for example, may be configured by benzocyclobutene or an acrylic organic material, but is not limited thereto.

A protection layer 115 is disposed on the fourth planarization layer 114d. The protection layer 115 is a layer for protecting a configuration below the protection layer 115 and may suppress the permeation of moisture or oxygen from the outside. For example, the protection layer 115 may be configured by a single layer or a double layer and for example, may use an epoxy or acryl-based polymer, but is not limited thereto.

A plurality of color filters CF may be further disposed on the protection layer 115. The plurality of color filters CF may overlap the plurality of sub pixels SP. Light released from the open area OA of each sub pixel SP passes through the plurality of color filters CF to travel to the outside of the display device 100. In contrast, external light which is incident to the display device 100 is absorbed by the plurality of color filters CF so that the external light is not reflected to the outside of the display device 100 again. Therefore, the color filter CF which absorbs external light and transmits only light of the sub pixel SP which is converted by the light conversion layer CCL to be released to the outside of the display device 100 is disposed to improve a display quality and improve a color reproductivity.

A second black matrix BM2 may be further disposed on the protection layer 115. The second black matrix BM2 may be disposed between the plurality of color filters CF. The second black matrix BM2 may shield light of the plurality of sub pixels SP so as not to cause the color mixture. Further, the second black matrix BM2 absorbs light incident to the display device 100 from the outside to minimize or at least reduce degradation of visibility due to external light which is reflected by the configuration in the display device 100. For example, the second black matrix BM2 includes a black component and may be formed of an opaque resin including a dye, but is not limited thereto.

A second substrate 116 is disposed on the color filter CF and the second black matrix BM2. The second substrate 116 is a component for supporting and protecting various components included in the display device 100 and may be formed of an insulating material. For example, the second substrate 116 may be formed of glass or resin. Further, the second substrate 116 may be formed of polymer or plastics or may be formed of a material having flexibility.

In the meantime, according to the present disclosure, it has been described that the color filter CF and the second black matrix BM2 are disposed on the protection layer 115, but the color filter CF and the second black matrix BM2 may be omitted, and are not limited thereto.

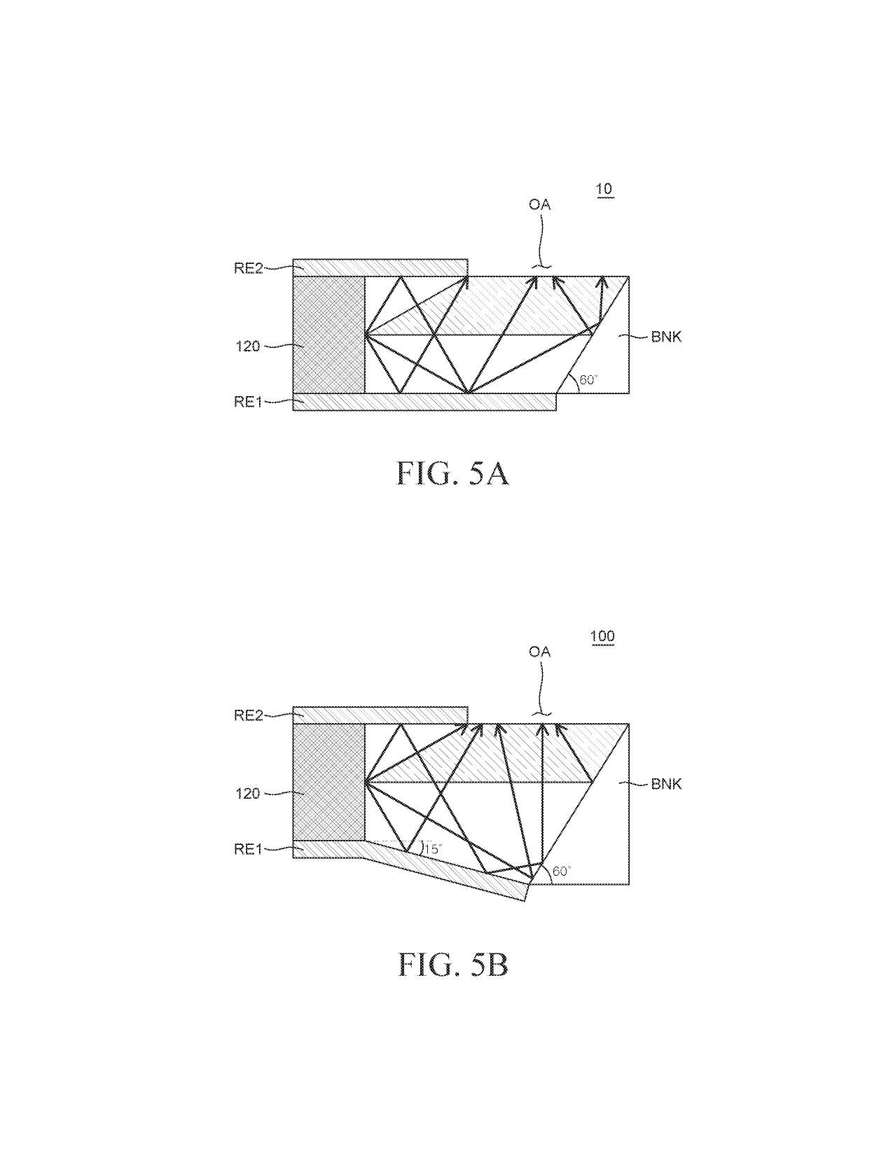

Hereinafter, an effect of improving a light conversion efficiency according to a structure of the display device 100 according to the exemplary embodiment of the present disclosure will be described with reference to FIGS. 5A to 7.

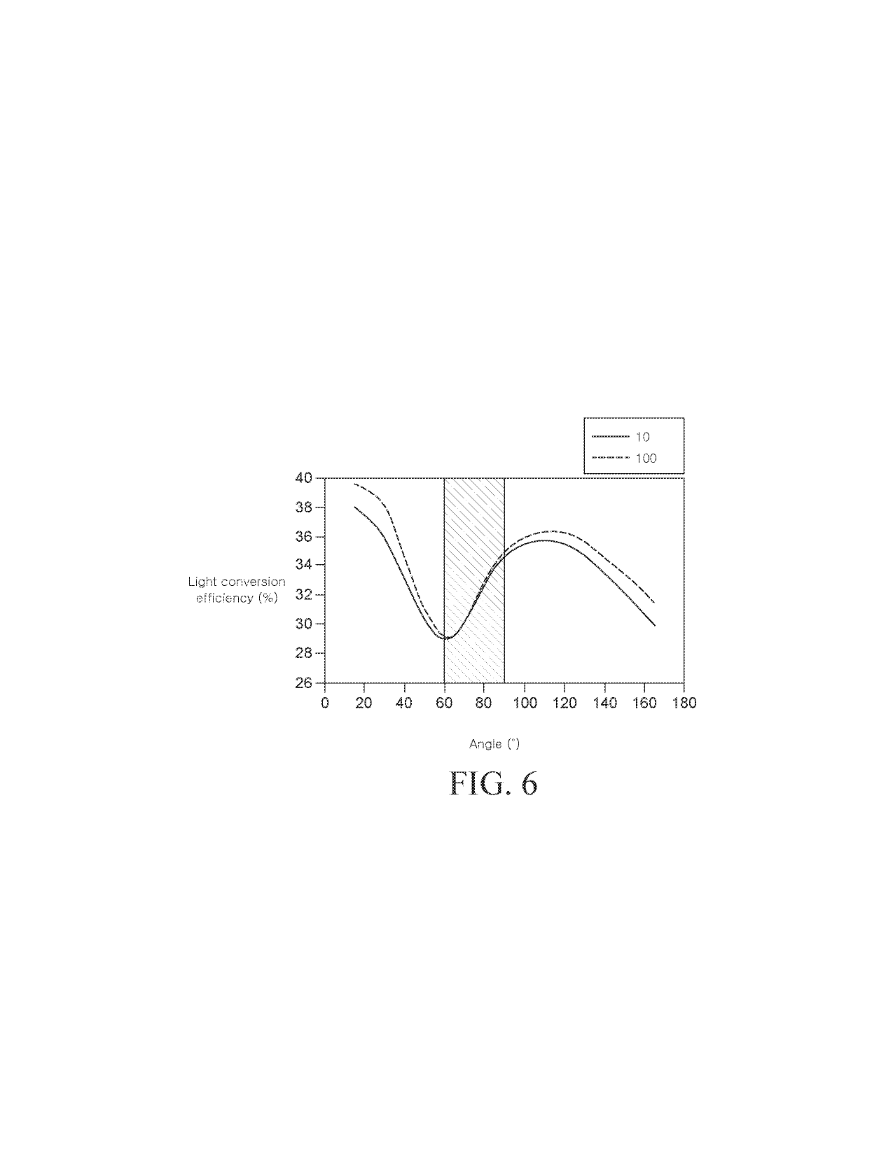

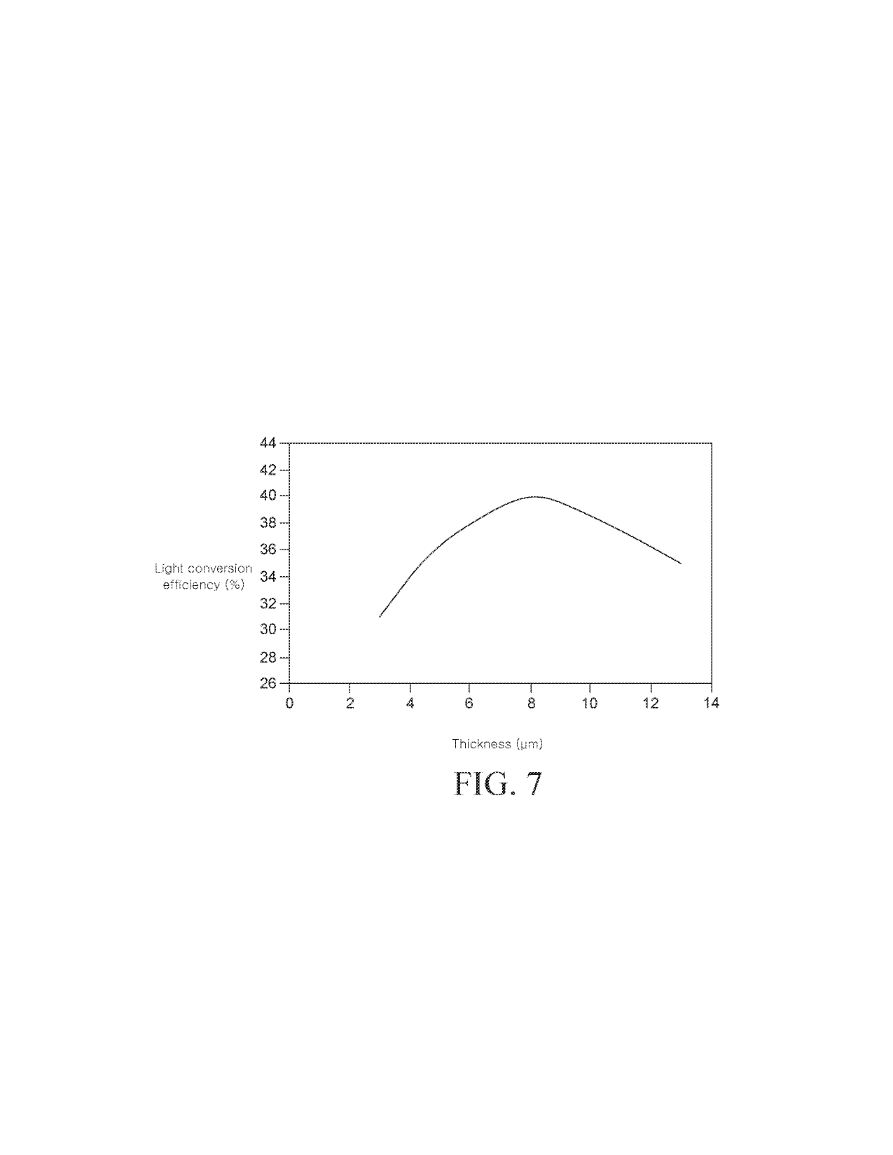

FIGS. 5A and 5B are views illustrating a placement relationship of a light emitting element, a first reflection electrode, a second reflection electrode, and a bank according to a comparative embodiment and an exemplary embodiment in the display device. FIG. 6 is a graph illustrating a light conversion efficiency according to an angle in each of display devices according to a comparative embodiment and an exemplary embodiment. FIG. 7 is a graph illustrating a light conversion efficiency according to a thickness of a light conversion layer. Specifically, FIG. 6 is a simulation result obtained by measuring a light conversion efficiency according to an angle of light emitted from a light emitting element 120 in a structure of a display device according to a comparative embodiment and one exemplary embodiment of FIGS. 5A and 5B.

Referring to FIG. 5A, in a display device 10 according to the comparative embodiment, the first reflection electrode RE1 is disposed below the light emitting element 120 and the second reflection electrode RE2 is disposed above the light emitting element 120. The first reflection electrode RE1 and the second reflection electrode RE2 are disposed to be parallel to each other and a length of the first reflection electrode RE1 may be longer than a length of the second reflection electrode RE2. A bank BNK having an angle of approximately 60 degrees is disposed on an end of the first reflection electrode RE1 and the light conversion layer CCL is disposed between the bank BNK and the light emitting element 120.

Referring to FIG. 5B, in a display device 100 according to the exemplary embodiment, the first reflection electrode RE1 is disposed below the light emitting element 120 and the second reflection electrode RE2 is disposed above the light emitting element 120. The second reflection electrode RE2 is horizontally disposed and a part of the first reflection electrode RE1 is disposed to have an inclined surface P3 with an angle of approximately 15 degrees and a length of the first reflection electrode RE1 may be longer than a length of the second reflection electrode RE2. A bank BNK having an angle of approximately 60 degrees is disposed on an end of the first reflection electrode RE1 and the light conversion layer CCL is disposed between the bank BNK and the light emitting element 120. That is, unlike the display device 10 according to the comparative embodiment, in the display device 100 according to the exemplary embodiment, the first reflection electrode RE1 may have an inclined surface P3 which is inclined below the light emitting element 120.

Referring to FIGS. 5A, 5B, and 6 together, when an angle of light which travels to an upper direction of the light emitting element 120 is defined as 0 degree and an angle of light which travels to a lower direction of the light emitting element 120 is defined as 180 degrees, it is confirmed that in each of the display device 10 of the comparative embodiment and the device 100 of the exemplary embodiment, a light conversion efficiency of light which travels in a direction perpendicular to the side surface of the light emitting element 120, for example, at an angle of 90 degrees is similar. For example, in FIGS. 5A and 5B, a hatched area is an area in which light traveling at an angle between 60 degrees and 90 degrees is represented. Further, as illustrated in FIG. 6, it is confirmed that in both the display device 10 of the comparative embodiment and the display device 100 of the exemplary embodiment, the light conversion efficiency of light traveling in an area between 60 degrees and 90 degrees is similar.

However, it is confirmed that the light conversion efficiency of light traveling in an area between 0 degree and 60 degrees and an area between 90 degrees and 180 degrees is higher in the display device 100 according to the exemplary embodiment than in the display device 10 according to the comparative embodiment. That is, some light traveling in an upper direction of the light emitting element 120, a diagonally upper direction of the light emitting element 120, a diagonally lower direction of the light emitting element 120, and a lower direction of the light emitting element 120 is reflected from a bottom surface of the second reflection electrode RE2, a top surface of the first reflection electrode RE1, and a side surface of the bank BNK to be converted into light of a different direction in the light conversion layer CCL. At this time, in the display device 100 according to the exemplary embodiment, the first reflection electrode RE1 is configured to have an inclined surface P3 which is inclined downwardly from the light emitting element 120. Therefore, the light conversion layer CCL located on the first reflection electrode RE1 may have a larger thickness and a length of a light path of light moving in the light conversion layer CCL may be increased. Therefore, in the display device 100 according to the exemplary embodiment, a length of the light path of light which is reflected on the side surfaces of the first reflection electrode RE1 and the bank BNK may be entirely increased and the light conversion efficiency may be increased.

Referring to FIG. 7, in a predetermined range, the larger the thickness of the light conversion layer CCL, the better the light conversion efficiency. For example, it is confirmed that as the thickness of the light conversion layer CCL is increased from approximately 3 um to 8 um, the light conversion efficiency is gradually increased. However, when the thickness of the light conversion layer CCL is excessively increased, for example, is increased to 8 um or more, the light efficiency may be reduced due to the light absorption. Therefore, in the display device 100 according to the exemplary embodiment of the present disclosure, the inclined surface P3 is formed in an area in which the light conversion layer CCL is disposed to adjust the thickness of the light conversion layer CCL in consideration of the light conversion efficiency.

Therefore, in the display device 100 according to the exemplary embodiment of the present disclosure, the inclined surface P3 is formed in an area in which the light conversion layer CCL is disposed to form the thickness of the light conversion layer CCL to be large and improve the light conversion efficiency. The inclined surface P3 is formed in an area in which the light conversion layer CCL is disposed so that the farther from the light emitting element 120, the larger the thickness of the light conversion layer CCL. Light emitted from the light emitting element 120 may travel toward the light conversion layer CCL by the first reflection electrode RE1 on a lower portion and a side portion of the light emitting element 120 and the second reflection electrode RE2 above the light emitting element 120. The first reflection electrode RE1 which encloses the side surface of the light conversion layer CCL and the second reflection electrode RE2 which covers at least a part of the top surface of the light conversion layer CCL are formed to easily reflect light emitted from the light emitting element 120 toward the light conversion layer CCL. At this time, the light conversion layer CCL has a large thickness so that the length of the light path of light moving in the light conversion layer CCL may be entirely increased and the light conversion efficiency may be improved. Therefore, the thickness of the light conversion layer CCL may be adjusted using the inclined surface P3 and the light conversion efficiency may be improved.

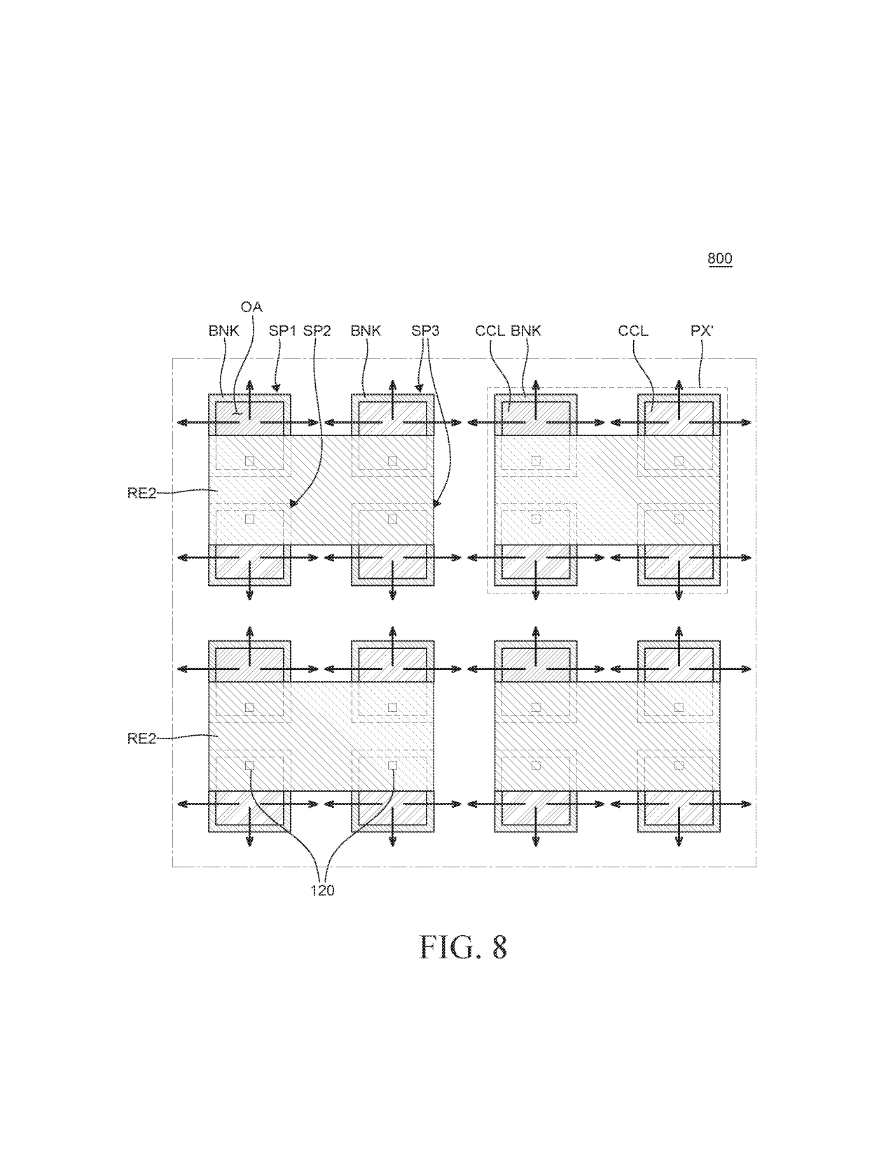

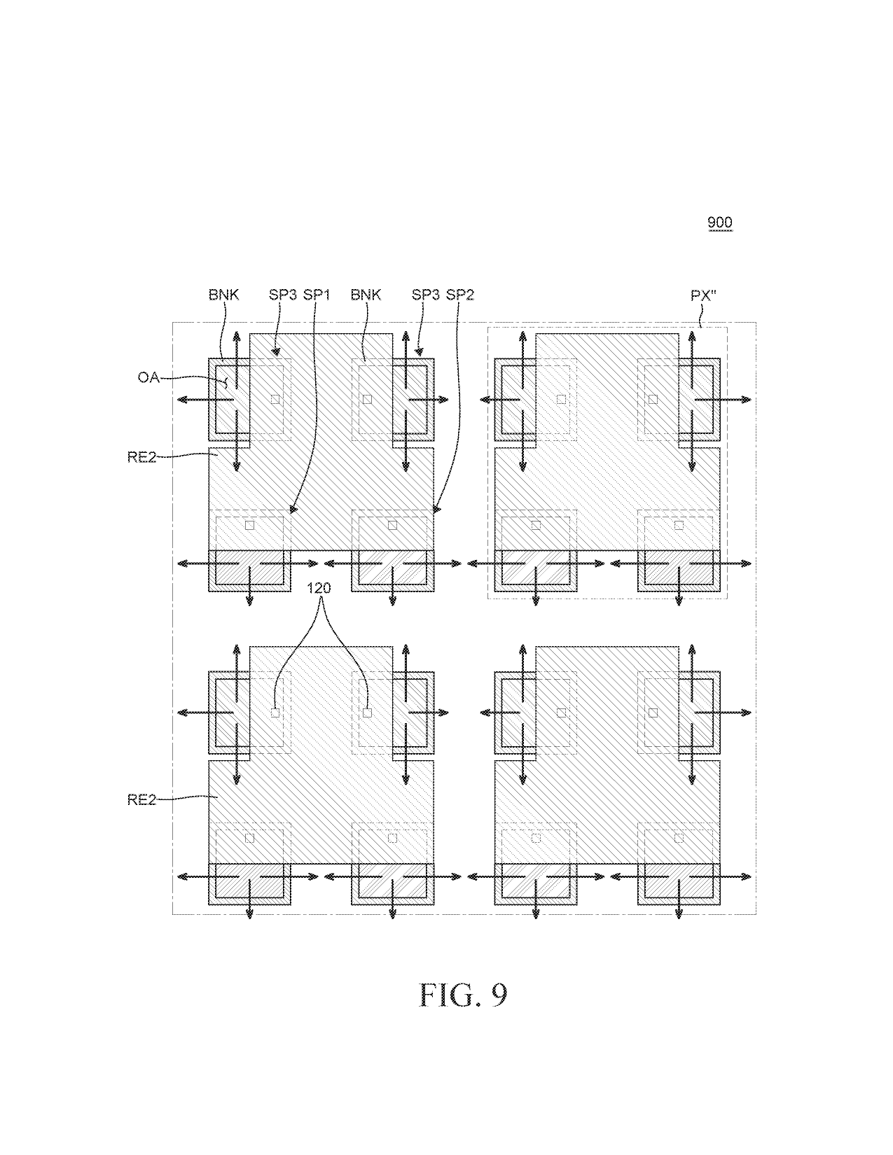

FIG. 8 is an enlarged plan view of a display device according to another exemplary embodiment of the present disclosure. FIG. 9 is an enlarged plan view of a display device according to still another exemplary embodiment of the present disclosure. The difference between display devices 800 and 900 of FIGS. 8 and 9 and the display device 100 of FIGS. 1 to 4 is a configuration of a plurality of pixels PX’ and PX” and placement of second reflection electrodes RE2, but the other configuration is substantially the same, so that a redundant description will be omitted.

Referring to FIGS. 8 and 9, a plurality of sub pixels SP which configure one pixel PX’ or PX” may share the second reflection electrode RE2. An amount of light released from the plurality of sub pixels SP in up, down, left, and right directions is uniformly configured to minimize or at least reduce the luminance deviation according to the viewing angle. Further, in some sub pixels SP, a light emitting direction is differently configured to configure different viewing angles for colors.

For example, referring to FIG. 8, one pixel PX’ may include one first sub pixel SP1, one second sub pixel SP2, and one pair of third sub pixels SP3. The first sub pixel SP1 and the second sub pixel SP2 may be disposed to be adjacent to each other in the column direction and one pair of third sub pixels SP3 may be disposed to be adjacent to each other in the column direction. The first sub pixel SP1 and the third sub pixel SP3 may be disposed to be adjacent to each other in a row direction and the second sub pixel SP2 and the third sub pixel SP3 may be disposed to be adjacent to each other in the row direction. In this case, the first sub pixel SP1, the second sub pixel SP2, and one pair of third sub pixels SP3 which are included in one pixel PX’ and form a rectangular area may share one second reflection electrode RE2. The second reflection electrode RE2 is formed to have a rectangular shape to cover a partial area of each of the first sub pixel SP1, the second sub pixel SP2, and one pair of third sub pixels SP3.

At this time, in one pair of third sub pixels SP3, the open area OA is symmetrically configured with respect to the second reflection electrode RE2 so that the luminance deviation according to the viewing angle of one pair of third sub pixels SP3 in the up, down, and left, and right may be reduced. Among the plurality of second reflection electrodes RE2, some second reflection electrodes RE2 may cover a lower area of the first sub pixel SP1 and an upper area of the second sub pixel SP2 and the remaining second reflection electrodes RE2 may cover an upper area of the third sub pixel SP3 and a lower area of the third sub pixel SP3. Therefore, as represented with arrows, in the plurality of first sub pixels SP1, light may be released only in an upper direction, a left direction, and a right direction and in the plurality of second sub pixels SP2, light may be released only in a lower direction, the left direction, and the right direction. Therefore, the luminance may intentionally vary according to the viewing angle for every sub pixel.

Referring to FIG. 9, one pixel PX’’ may include one first sub pixel SP1, one second sub pixel SP2, and one pair of third sub pixels SP3. One first sub pixel SP1 and one second sub pixel SP2 may be disposed to be adjacent to each other in the row direction and one pair of third sub pixels SP3 may be disposed to be adjacent to each other in the row direction . The first sub pixel SP1 and the third sub pixel SP3 may be disposed to be adjacent to each other in the column direction and the second sub pixel SP2 and the third sub pixel SP3 may be disposed to be adjacent to each other in the column direction. In this case, the first sub pixel SP1, the second sub pixel SP2, and one pair of third sub pixels SP3 which are adjacent to each other and form a rectangular area may share one second reflection electrode RE2. The second reflection electrode RE2 may be formed by a rectangular part which covers an upper area (or a lower area) of the first sub pixel SP1 and an upper area (or a lower area) of the second sub pixel SP2 disposed in the same row and another rectangular part which extends to an area between the pair of third sub pixels SP3 from the rectangular part to cover a left area and a right area of each of the pair of third sub pixels SP3.

At this time, in one pair of third sub pixels SP3, the open area OA is symmetrically configured with respect to the second reflection electrode RE2 so that the luminance deviation according to the viewing angle of one pair of third sub pixels SP3 in the up, down, and left, and right may be reduced. The second reflection electrode RE2 may cover the left area of the third sub pixel SP3 and a right area of the third sub pixel SP3 adjacent in the row direction and cover the upper area of the first sub pixel SP1 and the upper area of the second sub pixel SP2. Therefore, the plurality of third sub pixels SP3 may be configured by some third sub pixels SP3 which emit light in an upper direction, a left direction, and a lower direction and the remaining third sub pixels SP3 which emit light in the lower direction, the upper direction, and the right direction. The plurality of first sub pixels SP1 may be configured to emit light only to the lower direction, the left direction, and the right direction and the plurality of second sub pixels SP2 may be configured to emit light only to the lower direction, the left direction, and the right direction. Accordingly, the plurality of third sub pixels SP3 may be configured such that the same level of amount of light is released to the upper direction and the lower direction and in the plurality of first sub pixels SP1 and the plurality of second sub pixels SP2, light is released in a specific direction to intentionally change the colors according to the viewing angle.

Accordingly, in the display devices 800 and 900 according to various exemplary embodiments of the present disclosure, the plurality of sub pixels SP shares the second reflection electrode RE2 and the plurality of sub pixels SP is disposed in different manners to change the color according to the viewing angle.

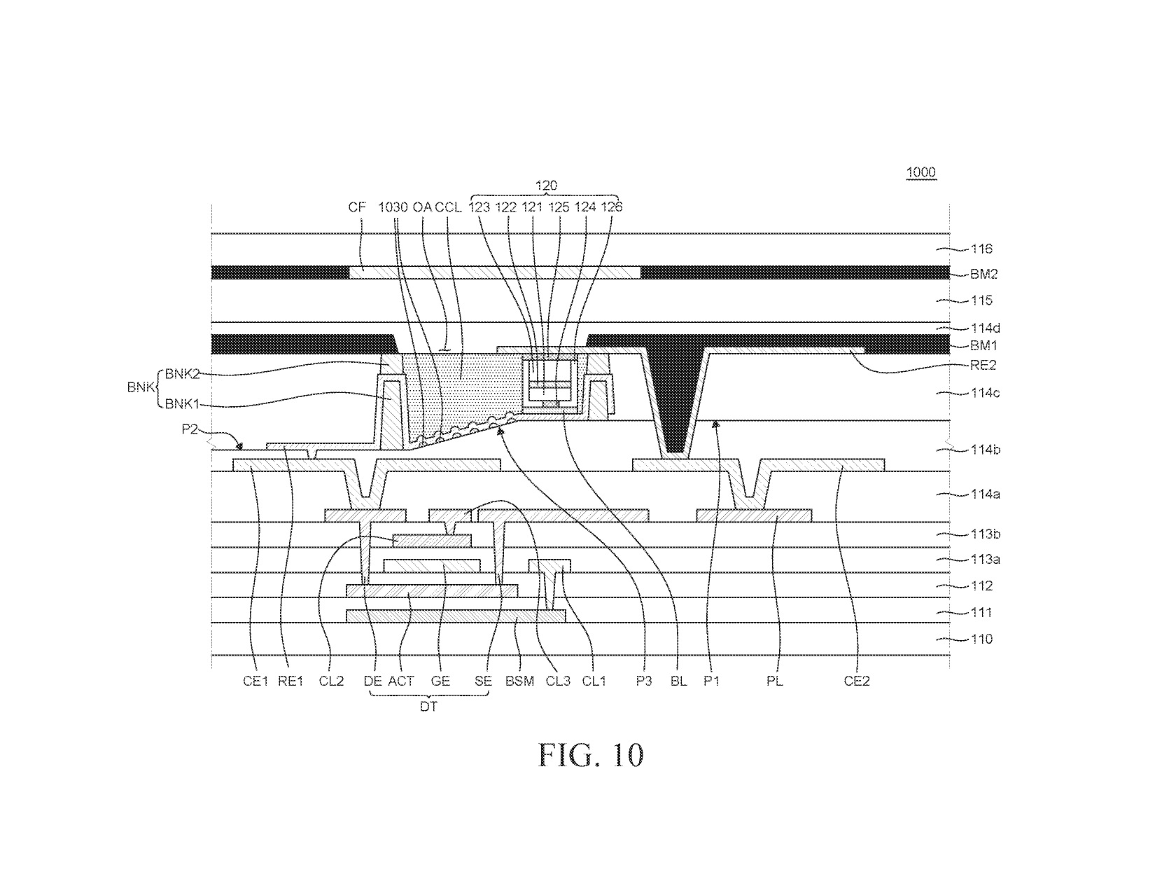

FIG. 10 is a cross-sectional view of a display device according to still another exemplary embodiment of the present disclosure. A display device 1000 of FIG. 10 is substantially the same as the display device 100 of FIGS. 1 to 4 except that a plurality of irregular patterns 1030 is further included, so that a redundant description will be omitted.

Referring to FIG. 10, the plurality of irregular patterns 1030 are disposed below the first reflection electrode RE1. For example, the plurality of irregular patterns 1030 may be disposed between the first reflection electrode RE1 and the inclined surface P3 of the second planarization layer 114b. The plurality of irregular patterns 1030 may be formed to have a constant size or various sizes. Further, the plurality of irregular patterns 1030 may be regularly disposed or irregularly disposed.

The first reflection electrode RE1 may have an irregular surface due to the plurality of irregular patterns 1030. The first reflection electrode RE1 may be formed along the plurality of irregular patterns 1030 so that the surface may be unevenly formed.

Accordingly, in the display device 1000 according to still another exemplary embodiment of the present disclosure, the surface of the first reflection electrode RE1 is unevenly formed by the plurality of irregular patterns 1030 so that light may be more easily reflected and scattered from the surface of the first reflection electrode RE1. Therefore, the light emitted from the light emitting element 120 is reflected and scattered from the surface of the first reflection electrode RE1 and is absorbed by a light conversion material of the light conversion layer CCL to be easily converted into light with a different color. Further, the light which is converted in the light conversion layer CCL may be easily released to the outside of the display device 1000.

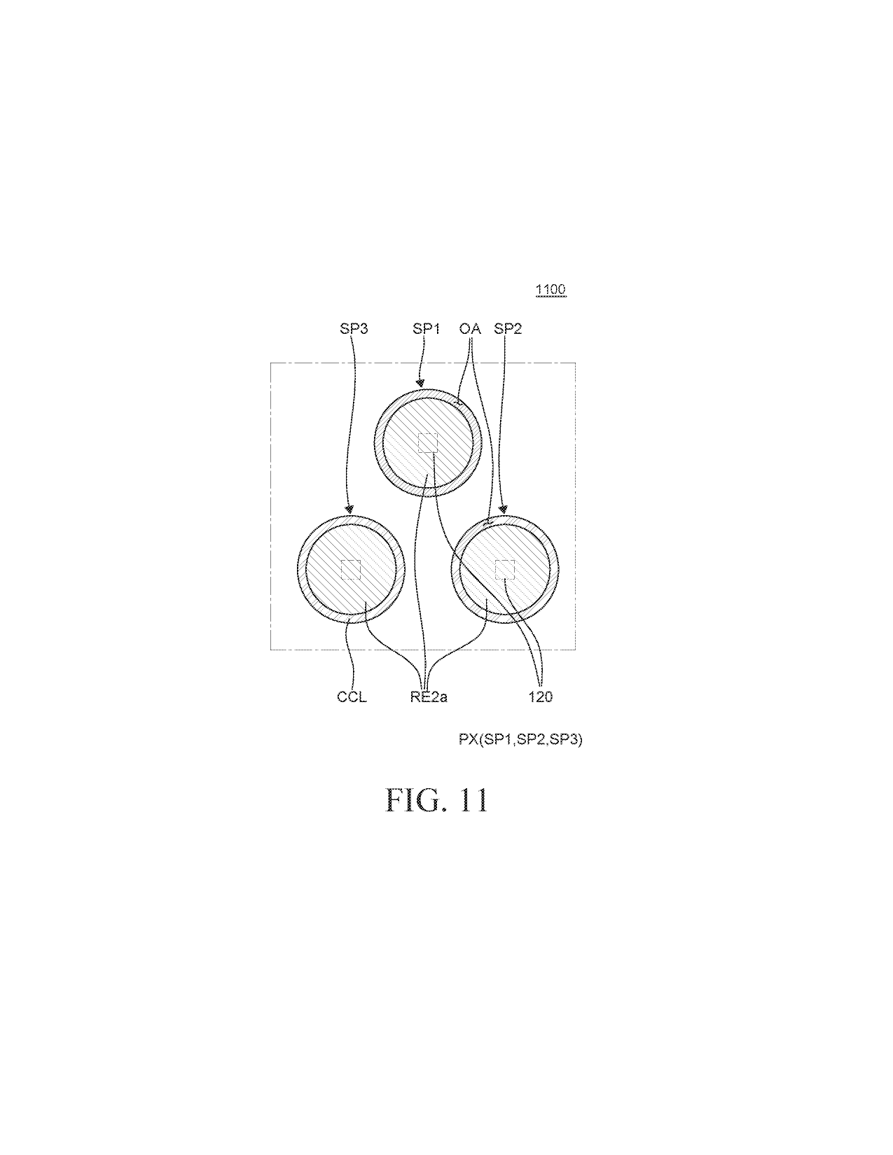

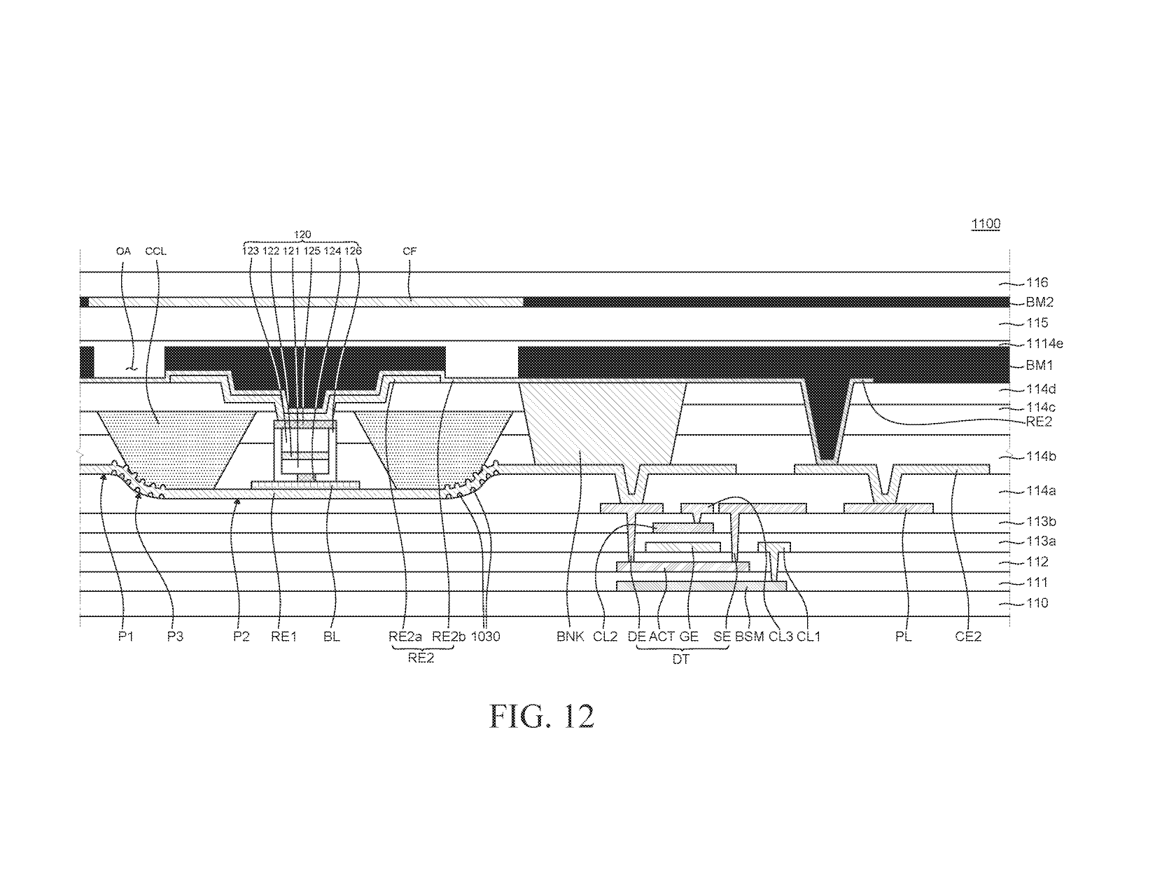

FIG. 11 is an enlarged plan view of a display device according to still another exemplary embodiment of the present disclosure. FIG. 12 is a cross-sectional view of a display device according to still another exemplary embodiment of the present disclosure. A display device 1100 of FIGS. 11 and 12 is different from the display device 100 of FIGS. 1 to 4 and the display device 1000 of FIG. 10 in that a light emitting element 120 is disposed on the second top surface P2 below the inclined surface P3 and a structure thereby is different, but the other configuration is substantially the same. Therefore, a redundant description will be omitted.

Referring to FIGS. 11 and 12, a planar shape of each of the plurality of sub pixels SP may be a circle. For example, a planar shape of the light conversion layer CCL of each of the plurality of sub pixels SP may be a donut shape or a circular shape and a planar shape of a reflection layer RE2a of a second reflection electrode RE2 may be a circle. At this time, the reflection layer RE2a of the second reflection electrode RE2 may be formed to have a circular shape which is smaller than that of the light conversion layer CCL and at least an edge portion of the light conversion layer CCL may be exposed from the reflection layer RE2a of the second reflection electrode RE2. Accordingly, the open area OA of each of the plurality of sub pixels SP may be formed to have a ring shape along the edge portion of the light conversion layer CCL. However, the planar shape of the plurality of sub pixels SP, the light conversion layer CCL, and the second reflection electrode RE2 may be various shapes, such as a rectangular shape, a triangular shape, other than the circular shape, but is not limited thereto.

A buffer layer 111, a gate insulating layer 112, a first interlayer insulating layer 113a, a second interlayer insulating layer 113b, a driving transistor DT, and a power line PL are disposed on the first substrate 110 and a first planarization layer 114a is disposed on the driving transistor DT and the power line PL.

A top surface of the first planarization layer 114a includes a first top surface P1 which is flat, an inclined surface P3 which obliquely extends from the first top surface P1, and a second top surface P2 which flatly extends from the inclined surface P3. The first top surface P1 and the second top surface P2 may be disposed to be parallel to one surface of the first substrate 110 and the inclined surface P3 which obliquely extends may be disposed between the first top surface P1 and the second top surface P2. A height of the first top surface P1 may be higher than a height of the second top surface P2.

The first top surface P1 may be disposed in an area between the plurality of sub pixels SP, the second top surface P2 may be disposed below the light emitting element 120 in each of the plurality of sub pixels SP, and the inclined surface P3 may be between the first top surface P1 and the second top surface P2. In each of the plurality of sub pixels SP, an area in which the light emitting element 120 is disposed may be formed to be concave by the second top surface P2 and the inclined surface P3. The first top surfaces P1 disposed in areas between the plurality of sub pixels SP may be connected to each other and may be formed in a mesh shape.

The plurality of irregular patterns 1030 are disposed on the inclined surface P3 of the first planarization layer 114a. The plurality of irregular patterns 1030 are patterns for forming an irregular structure on a surface of the first reflection electrode RE1. The first reflection electrode RE1 formed on the plurality of irregular patterns 1030 is formed to have a surface shape along a surface shape of the plurality of irregular patterns 1030 to reflect and scatter light.

The first reflection electrode RE1 is disposed on the first planarization layer 114a and the plurality of irregular patterns 1030. The first reflection electrodes RE1 is an electrode for electrically connecting the light emitting element 120 and the driving transistor DT. Further, the first reflection electrode RE1 may reflect the light emitted from the light emitting element 120 to the upper portion of the first substrate 110. The first reflection electrode RE1 may be electrically connected to the driving transistor DT through a contact hole of the first planarization layer 114a formed on the first top surface P1. The first reflection electrode RE1 extends from the first top surface P1 of the first planarization layer 114a to the inclined surface P3 and the second top surface P2 to cover the entire area in which the light emitting element 120 and the light conversion layer CCL are disposed. The first reflection electrode RE1 which covers the inclined surface P3 and the second top surface P2 may be formed in a concave cup shape. Therefore, the first reflection electrode RE1 which is concave may easily reflect light which is directed to the lateral direction, among the light emitted from the light emitting element 120, to the top of the first substrate 110. The first reflection electrodes RE1 may include an opaque conductive layer, such as silver (Ag), aluminum (Al), molybdenum (Mo), titanium (Ti), or an alloy thereof. The first reflection electrode RE1 may further include a transparent conductive layer, such as indium tin oxide (ITO), in the opaque conductive layer, in consideration of the resistance, but is not limited thereto.

The connection electrode CE2 is disposed on the first planarization layer 114a. The connection electrode CE2 is an electrode which electrically connects the power line PL and the second reflection electrode RE2. The connection electrode CE2 may be electrically connected to the power line PL through a contact hole of the first planarization layer 114a. The connection electrode CE2 may be electrically connected to the second reflection electrode RE2 through contact holes of the second planarization layer 114b, the third planarization layer 114c, and the fourth planarization layer 114d. The connection electrode CE2 may be formed on the same layer with the same material as the first reflection electrode RE1.

Next, a bonding layer BL is disposed on the first reflection electrode RE1 in each of the plurality of sub pixels SP and the light emitting element 120 is disposed on the bonding layer BL. The bonding layer BL and the light emitting element 120 may be disposed on the second top surface P2 of the first planarization layer 114a.

Next, the second planarization layer 114b is disposed on the first planarization layer 114a, the first reflection electrode RE1, and the connection electrode CE2 and the third planarization layer 114c is disposed on the second planarization layer 114b. After forming the second planarization layer 114b and the third planarization layer 114c on the entire surface of the first substrate 110, a part of the second planarization layer 114b and the third planarization layer 114c in an area in which the light conversion layer CCL will be disposed is removed to form the second planarization layer 114b and the third planarization layer 114c. The second planarization layer 114b and the third planarization layer 114c may be disposed so as to enclose each of the plurality of light emitting elements 120. The second planarization layer 114b and the third planarization layer 114c may fix the plurality of light emitting elements 120 together with the bonding layer BL. At least a part of the second planarization layer 114b and the third planarization layer 114c which overlaps the inclined surface P3 and the second top surface P2 is removed to form a space in which the light conversion layer CCL is filled. The second planarization layer 114b and the third planarization layer 114c may be configured by a single layer or a double layer, and for example, configured by benzocyclobutene or an acrylic organic material, but are not limited thereto.

In the meantime, even though in FIG. 12, it is illustrated that the second planarization layer 114b and the third planarization layer 114c enclose the light emitting element 120, the second planarization layer 114b and the third planarization layer 114c which enclose the light emitting element 120 may be omitted, but the present disclosure is not limited thereto.

The light conversion layer CCL is disposed on the first reflection electrode RE1 in each of the plurality of sub pixels SP. The light conversion layer CCL may convert light emitted from the light emitting element 120 into different color light. The light conversion layer CCL may be disposed so as to enclose the plurality of light emitting elements 120 and the second planarization layer 114b and the third planarization layer 114c which fix the plurality of light emitting elements 120. The light conversion layer CCL may be disposed so as to overlap the inclined surface P3 and the second top surface P2. The light conversion layer CCL may be filled in a space formed by removing the second planarization layer 114b and the third planarization layer 114c. A thickness of the light conversion layer CCL may be formed to be larger than the thickness of the light emitting element 120.

In the meantime, the light conversion layer CCL may have a larger thickness due to the inclined surface P3 and the second top surface P2 of the first planarization layer 114a. For example, when the first planarization layer 114a is formed only by the first top surface P1 without the concave inclined surface P3 and the second top surface P2, the thickness of the light conversion layer CCL disposed on the first planarization layer 114a and the first reflection electrode RE1 may also be reduced. In the meantime, as a concave groove is formed in the first planarization layer 114a in an area in which the light conversion layer CCL is disposed, the entire thickness of the light conversion layer CCL may be increased so that the light conversion efficiency of the light conversion layer CCL may also be improved.

Next, the fourth planarization layer 114d is disposed on the third planarization layer 114c, the light conversion layer CCL, and the light emitting element 120. The fourth planarization layer 114d may planarize upper portions of the light emitting element 120 and the light conversion layer CCL. The fourth planarization layer 114d may be configured by a single layer or a double layer, and for example, may be configured by benzocyclobutene or an acrylic organic material, but is not limited thereto.

In the meantime, the fourth planarization layer 114d may include a contact hole through which the second reflection electrode RE2 is in contact with the light emitting element 120. The contact hole of the fourth planarization layer 114d may be formed in a step shape which is widened from a lower side toward an upper side. As the contact hole of the fourth planarization layer 114d has a step shape, the second reflection electrode RE2 formed on the fourth planarization layer 114d may also have a step shape. Therefore, the fourth planarization layer 114d may provide a contact hole for forming the second reflection electrode RE2 in a step shape in the area of the plurality of sub pixels SP and provide a flat top surface in an area between the plurality of sub pixels SP.

Next, in each of the plurality of sub pixels SP, a bank BNK which encloses the light emitting element 120 and the light conversion layer CCL is disposed. The bank BNK is disposed in the area between the plurality of sub pixels SP to suppress color mixture of light of the plurality of sub pixels SP. The bank BNK is disposed in the area between the plurality of sub pixels SP and may be formed in a mesh shape. The bank BNK may be disposed on the first top surface P1 of the first planarization layer 114a. A part of the second planarization layer 114b, the third planarization layer 114c, and the fourth planarization layer 114d which overlap the first top surface P1 is removed and the bank BNK may be formed in the space. The bank BNK may be formed by dispersing various light scattering materials in an insulating material. For example, the bank BNK includes a light scattering material, such as titanium dioxide (TiO2) to change a path of light by scattering and reflecting some light which is directed to the side direction of the light emitting element 120, among light emitted from the light emitting element 120, to an upper direction of the light emitting element 120 and improves the light extraction efficiency.

A second reflection electrode RE2 is disposed on the fourth planarization layer 114d and the bank BNK. The second reflection electrode RE2 is an electrode for electrically connecting the light emitting element 120 and the power line PL. The second reflection electrode RE2 may be electrically connected to the connection electrode CE2 through contact holes of the fourth planarization layer 114d, the third planarization layer 114c, and the second planarization layer 114b. The second reflection electrode RE2 may be electrically connected to the light emitting element 120 through a step-shaped contact hole of the fourth planarization layer 114d. Accordingly, the light emitting element 120 may be electrically connected to the power line PL through the second reflection electrode RE2 and the connection electrode CE2.

The second reflection electrode RE2 may be formed with a double-layered structure of a reflection layer RE2a and a transparent layer RE2b. The reflection layer RE2a may be disposed on the fourth planarization layer 114d and the transparent layer RE2b may be disposed on the reflection layer RE2a. The reflection layer RE2a may be formed of an opaque conductive layer, such as silver (Ag), aluminum (Al), molybdenum (Mo), titanium, or an alloy thereof and the transparent layer RE2b may be formed of a transparent conductive layer, such as indium tin oxide (ITO).

The reflection layer RE2a is a layer which reflects light emitted from the light emitting element 120 toward the light conversion layer CCL and the first reflection electrode RE1 in the vicinity of the light emitting element 120. The reflection layer RE2a may be disposed on the light emitting element 120. The reflection layer RE2a may be disposed only in a part of the second reflection electrode RE2. For example, the reflection layer RE2a may overlap the light emitting element 120 and a part of the light conversion layer CCL which encloses the light emitting element 120. The reflection layer RE2a may extend from an area on the second top surface P2 of the first planarization layer 114a toward an area on the inclined surface P3 to cover the light emitting element 120. The reflection layer RE2a may be disposed so as to overlap the second top surface P2 of the first planarization layer 114a and may not overlap the inclined surface P3, such that the part of the light conversion layer CCL disposed on the inclined surface P3 is exposed from the reflection layer RE2a of the second reflection electrode RE2. As the reflection layer RE2a is disposed in a step-shaped contact hole of the fourth planarization layer 114d so that a cross-sectional shape of the reflection layer RE2a may be a step shape.

The transparent layer RE2b is a layer for electrically connecting the light emitting element 120 and the power line PL. The transparent layer RE2b may be disposed in the entire second reflection electrode RE2. For example, the transparent layer RE2b may be disposed so as to overlap the light conversion layer CCL, the light emitting element 120, and the bank BNK and may be electrically connected to the connection electrode CE2 through contact holes of the fourth planarization layer 114d, the third planarization layer 114c, and the second planarization layer 114b.

The transparent layer RE2b may overlap the open area OA. The open area OA is an area in which light converted in the light conversion layer CCL is released and in the open area OA, the reflection layer RE2a is not disposed, but the transparent layer RE2b may be disposed. Only the transparent layer RE2b is disposed in the open area OA so that light converted in the light conversion layer CCL may be extracted to the outside. The open area OA may be disposed so as to be spaced apart from the light emitting element 120 with a predetermined distance. The open area OA may be formed in a closed loop shape which encloses the light emitting element 120.

A first black matrix BM1 is disposed on the second reflection electrode RE2 and the fourth planarization layer 114d. The first black matrix BM1 may be disposed so as to cover the remaining area excluding the open area OA. For example, the first black matrix BM1 may be disposed so as to cover the reflection layer RE2a of the second reflection electrode RE2. The transparent layer RE2b of the second reflection electrode RE2 which overlaps the open area OA may be exposed from the first black matrix BM1. The first black matrix BM1 may be disposed so as to be spaced apart from the part of the light conversion layer CCL exposed from the reflection layer. Therefore, light which is converted in the light conversion layer CCL may be directed to the outside through the open area OA in which only the transparent layer RE2b is disposed. The first black matrix BM1 may shield light of the plurality of sub pixels SP so as not to cause the color mixture. Further, the first black matrix BM1 absorbs light incident to the display device 1100 from the outside to minimize or at least reduce degradation of visibility due to external light which is reflected by the configuration in the display device 1100. For example, the first black matrix BM1 includes a black component and may be formed of an opaque resin including a dye, but is not limited thereto.

A fifth planarization layer 1114e is disposed between the first black matrix BM1 and the protection layer 115. The fifth planarization layer 1114e may planarize an upper portion of the first black matrix BM1. The fifth planarization layer 1114e may be configured by a single layer or a double layer, and for example, configured by benzocyclobutene or an acrylic organic material, but is not limited thereto.

In the display device 1100 according to still another exemplary embodiment of the present disclosure, an inclined surface P3 is formed on an insulating layer disposed below the light emitting element 120 and the first reflection electrode RE1, for example, on the first planarization layer 114a to obliquely form the first reflection electrode RE1. Further, light which travels in the lateral direction may be easily reflected to the top of the first substrate 110. At this time, the reflection layer RE2a of the second reflection electrode RE2 disposed above the light emitting element 120 is also formed in a step structure which is upwardly widened to guide the light emitted from the light emitting element 120 to the open area OA. Light emitted from the light emitting element 120 is reflected between the first reflection electrode RE1 and the second reflection electrode RE2 and may travel toward the inside of the light conversion layer CCL in the lateral direction of the light emitting element 120. In this process, light of the light emitting element 120 may be converted into light of a different color and light which is converted in the light conversion layer CCL may travel toward the open area OA by the first reflection electrode RE1 on the inclined surface P3. At this time, some of light which are not output through the open area OA, but continue to travel in the lateral direction of the light emitting element 120 may change the light path by the bank BNK including the light scattering material and may be directed to the open area OA. Accordingly, light emitted from the light emitting element 120 moves in the light conversion layer CCL to be converted in light with a different color by the first reflection electrode RE1 which is obliquely formed below the light emitting element 120, the second reflection electrode RE2 which is disposed above the light emitting element 120 and has a step shape, and the bank BNK which is disposed so as to enclose the light conversion layer CCL and includes a light scattering material. The converted light may be easily output to the outside of the display device 1100 through the open area OA. Therefore, the light conversion efficiency and the light extraction efficiency may be improved by the first reflection electrode RE1, the second reflection electrode RE2, and the bank BNK and the luminance of the display device 1100 may be improved.

The exemplary embodiments of the present disclosure can also be described as follows:

According to an embodiment of the present disclosure, a display device includes a first substrate, a planarization layer which is disposed on the first substrate and includes a first top surface, a second top surface having a height lower than that of the first top surface, and an inclined surface, a first reflection electrode which is at least partially disposed on the inclined surface of the planarization layer, a light emitting element on the first reflection electrode, and a second reflection electrode which is disposed so as to cover the light emitting element. The light emitting element is disposed on any one of the first top surface and the second top surface.

The display device may further include a light conversion layer which is disposed on the first reflection electrode and encloses the light emitting element, and the second reflection electrode may cover a part of the light conversion layer.

The display device may further include a bank which is disposed on the planarization layer and encloses the light emitting element and the light conversion layer, and at least a part of an area in the bank may overlap the inclined surface.

The light emitting element may be disposed on the first top surface in the area in the bank and a part of the light conversion layer may overlap the inclined surface and the other part of the light conversion layer may overlap the first top surface.

The second reflection electrode may extend from an area on the first top surface toward an area on the inclined surface to cover the light emitting element and a part of the light conversion layer disposed on the inclined surface may be exposed from the second reflection electrode.

The farther from the light emitting element, the larger a thickness of the light conversion layer.

The bank may include a first bank disposed on the planarization layer, and a second bank disposed on the first bank.

The first bank may be disposed on the first top surface and the second top surface and a thickness of a part of the first bank disposed on the second top surface may be larger than a thickness of the other part of the first bank disposed on the first top surface.

The first reflection electrode may be in contact with a top surface and a side surface of the first bank and the first reflection electrode may be disposed between the first bank and the second bank.

The light emitting element may be disposed on the second top surface and the part of the light conversion layer may overlap the second top surface and the other part of the light conversion layer may overlap the inclined surface.

The second reflection electrode may include a reflection layer disposed on the light emitting element and is disposed in a part of the second reflection electrode, and a transparent layer which is disposed on the reflection layer and is disposed in the entire second reflection electrode.

The reflection layer of the second reflection electrode may extend from an area on the second top surface toward an area on the inclined surface to cover the light emitting element and the part of the light conversion layer disposed on the inclined surface may be exposed from the reflection layer of the second reflection electrode.

The part of the light conversion layer exposed from the reflection layer may be an edge portion of the light conversion layer.

A cross-sectional shape of the reflection layer may be a step shape.

The display device may further include a black matrix disposed on the second reflection electrode so as to overlap the reflection layer, and the black matrix may be disposed so as to be spaced apart from the part of the light conversion layer exposed from the reflection layer.

The display device may further include a plurality of irregular patterns disposed between the inclined surface of the planarization layer and the first reflection electrode, and a part of the first reflection electrode disposed on the inclined surface may have a surface along a shape of the plurality of irregular patterns.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a first substrate;
a planarization layer on the first substrate, the planarization layer including a first top surface, a second top surface having a height that is lower than a height of the first top surface, and an inclined surface;
a first reflection electrode which is at least partially disposed on the inclined surface of the planarization layer;
a light emitting element on the first reflection electrode; and
a second reflection electrode that covers the light emitting element,
wherein the light emitting element is on any one of the first top surface and the second top surface.

2. The display device according to claim 1, further comprising:
a light conversion layer on the first reflection electrode, the light conversion layer enclosing the light emitting element,
wherein the second reflection electrode covers a part of the light conversion layer.

3. The display device according to claim 2, further comprising:
a bank on the planarization layer, the bank enclosing the light emitting element and the light conversion layer,
wherein at least a part of an area in the bank overlaps the inclined surface.

4. The display device according to claim 3, wherein the light emitting element is on the first top surface in the area in the bank and a part of the light conversion layer overlaps the inclined surface and another part of the light conversion layer overlaps the first top surface.

5. The display device according to claim 4, wherein the second reflection electrode extends from an area on the first top surface toward an area on the inclined surface and covers the light emitting element and a part of the light conversion layer on the inclined surface is exposed from the second reflection electrode.

6. The display device according to claim 4, wherein the farther from the light emitting element, the larger a thickness of the light conversion layer.

7. The display device according to claim 3, wherein the bank includes:
a first bank on the planarization layer; and
a second bank on the first bank.

8. The display device according to claim 7, wherein the first bank is on the first top surface and the second top surface and a thickness of a part of the first bank disposed on the second top surface is larger than a thickness of another part of the first bank disposed on the first top surface.

9. The display device according to claim 7, wherein the first reflection electrode is in contact with a top surface and a side surface of the first bank and the first reflection electrode is between the first bank and the second bank.

10. The display device according to claim 3, wherein the light emitting element is on the second top surface and the part of the light conversion layer overlaps the second top surface and another part of the light conversion layer overlaps the inclined surface.

11. The display device according to claim 4, further comprising:
a black matrix in a remaining area excluding an area in which the light conversion layer is disposed.

12. The display device according to claim 10, wherein the second reflection electrode includes:
a reflection layer on the light emitting element and is in a part of the second reflection electrode; and
a transparent layer on the reflection layer and is disposed in the entire second reflection electrode.

13. The display device according to claim 12, wherein the reflection layer of the second reflection electrode extends from an area on the second top surface toward an area on the inclined surface to cover the light emitting element and the part of the light conversion layer disposed on the inclined surface is exposed from the reflection layer of the second reflection electrode.

14. The display device according to claim 13, wherein the part of the light conversion layer exposed from the reflection layer is an edge portion of the light conversion layer.

15. The display device according to claim 12, wherein a cross-sectional shape of the reflection layer is a step shape.

16. The display device according to claim 12, wherein the reflection layer has a step structure which is upwardly widened.

17. The display device according to claim 12, further comprising:
a black matrix on the second reflection electrode, the black matrix overlapping the reflection layer,
wherein the black matrix is spaced apart from the part of the light conversion layer exposed from the reflection layer.

18. The display device according to claim 1, further comprising:
a plurality of irregular patterns between the inclined surface of the planarization layer and the first reflection electrode,
wherein a part of the first reflection electrode disposed on the inclined surface has a surface along a shape of the plurality of irregular patterns.
